(19) United States
(12) Patent Application Publication
(10) Pub. No.: US 2015/0318120 A1
(43) Pub. Date: Nov. 5, 2015

(54) CARBON NANOTUBE-GRAPHENE COMPOSITE

(71) Applicant: Empire Technology Development LLC., Wilmington, DE (US)

(72) Inventor: Peng He, Fairborn, OH (US)

(21) Appl. No.: 14/649,498

(22) PCT Filed: Jan. 30, 2013
(86) PCT No.: PCT/US13/23904

§ 371 Date: Jun. 3, 2015

(51) Int. Cl. H01G 11/36; H01G 11/52; C23C 16/52; C23C 16/46; C23C 16/26

(52) U.S. Cl. CPC H01G 11/36; C23C 16/46; C23C 16/463; C23C 16/26; C23C 16/52; H01G 11/52

(57) ABSTRACT

Technologies are generally described for various carbon nanotube-graphene composites. In some examples, the carbon nanotube-graphene composites may include an array of graphene sheets arranged in a substantially graphitic structure that may be separated by a collection of carbon nanotubes located between at least a portion of the graphene sheets. Various example capacitor devices are described that may include the carbon nanotube-graphene composites. Such capacitor devices may include two parallel electrodes, one or both of which may include the carbon nanotube-graphene composites. The space between the parallel electrodes may be contacted with one or more electrolytes or dielectric materials. Such capacitor devices may have high electrode surface area and may avoid pore effects, in comparison to high surface area porous electrodes without the carbon nanotube-graphene composite electrodes.

### BACKGROUND

Unless otherwise indicated herein, the materials described in this section are not prior art to the claims in this application and are not admitted to be prior art by inclusion in this section.

Supercapacitors are of increasing interest for application as high-power energy-storage devices. Compared with batteries, supercapacitors may have higher power density and a higher number of charge-discharge cycles. To improve the performance of supercapacitors, an electrode material with high conductivity and large surface area may be desirable. For example, activated charcoal is commonly used in electrochemical double layer supercapacitors (EDLCs), in part due to high specific surface area, low cost and processability. However, the capacitance increase has been limited because many of the pores in activated charcoal are smaller than hydrated/solvated ions. The energy storage capacity of activated charcoal based supercapacitors is typically described below 200 Farads per gram (F/g). Activated charcoal based supercapacitors may be further limited due to relatively low electrical conductivity and low power density.

Carbon nanotube (CNT) and graphene electrodes have been reported with large specific surface areas and high electrical conductivity, with initial reports of specific capacitance as high as 100-260 F/g and 50-120 F/g in aqueous and organic solutions, respectively. The results were still much lower than the theoretical capacitances, perhaps due to agglomeration of CNT and graphene sheets. Thus, for CNT and graphene electrodes, it may be desirable for the CNTs and graphene sheets to be well separated and to have good electrolyte contact. Some computational models describe parallel graphene layers separated by perpendicularly aligned CNTs. An experimental strategy to prepare a similar structure may provide a maximum specific capacitance of 385 F/g. However, reported experimental strategies are typically complex and inconvenient. For example, one reported route includes: synthesizing graphene oxide from natural graphite by a modified Hummers method; suspending the graphene oxide in water to give a dispersion, which is subjected to dialysis to completely remove residual salts and acids; dispersing the purified graphene oxide in water; exfoliation of the dispersed graphene oxide by ultrasonication; addition of Co(NO₃)₂.6H₂O and urea; heating the resulting suspension with microwaves; filtration and desiccation to form graphene oxide sheets with Co catalyst particles; heating in a horizontal quartz tubular reactor to 750° C. in argon; and reduction of the graphene oxide and chemical vapor deposition of CNT using hydrogen and carbon dioxide, among other steps. Not only are such methods complex and inconvenient, the produced product may include graphene oxide defects (from incomplete reduction to graphene), relatively disordered arrangements of the graphene/CNT sheets due to the stepwise and dispersive nature of production, and relatively non-uniform CNT lengths due to the dispersive nature of production.

The present disclosure appreciates that preparing high surface area carbon based capacitor electrodes especially graphene/CNT hybrid electrodes, may be a complex undertaking.

### SUMMARY

The following summary is illustrative only and is not intended to be in any way limiting. In addition to the illustrative aspects, embodiments, and features described above, further aspects, embodiments, and features will become apparent by reference to the drawings and the following detailed description.

The present disclosure generally describes technologies for carbon nanotube-graphene composites and electrochemical capacitors including carbon nanotube-graphene composites.

Various methods for preparing carbon nanotube-graphene composites are described herein. In some examples, methods for preparing a carbon nanotube-graphene composite may include: providing a graphite substrate that includes stacked graphene sheets, providing a carbon nanotube chemical vapor deposition catalyst, inserting the carbon nanotube chemical vapor deposition catalyst between at least a portion of the stacked graphene sheets of the graphite substrate, and/or heating the carbon nanotube chemical vapor deposition catalyst in contact with a chemical vapor deposition feedstock to a temperature suitable for growing carbon nanotubes. Various example methods may also include growing carbon nanotubes from the heated carbon nanotube chemical vapor deposition catalyst between the stacked graphene sheets of the graphite substrate for a period of time sufficient to separate at least a portion of the stacked graphene sheets of the graphite substrate using the growing carbon nanotubes. Several example methods may include cooling the carbon nanotubes and the separated graphene sheets to provide the carbon nanotube-graphene composite.

Various systems for preparing carbon nanotube-graphene composites are described herein. In some examples, systems for preparing carbon nanotube-graphene composites may include one or more of: a reaction chamber; a chemical reservoir: a pressure sensor; a heater; a temperature sensor; a gas source; and/or a controller. The reaction chamber may be configured to receive a graphite substrate that includes stacked graphene sheets. The chemical reservoir may be configured to direct a carbon nanotube chemical vapor deposition catalyst or a precursor thereof to the reaction chamber. The pressure sensor may be configured to measure a pressure in the reaction chamber. The heater may be configured to heat the reaction chamber in a range from about 550° C. to about 1000° C. The temperature sensor may be configured to measure a temperature in the reaction chamber. The gas source may be configured to direct to the reaction chamber one or more of: a reducing gas; an oxidizing gas; an inert gas; and/or a chemical vapor deposition feedstock suited for carbon nanotube deposition. The controller may be coupled to one or more of: the reaction chamber, the chemical reservoir, the gas source, the pressure sensor, the heater, and/or the temperature sensor. In several examples of the system, the controller may be programmed to: provide a graphite substrate that includes stacked graphene sheets to the reaction chamber; provide a carbon nanotube chemical vapor deposition catalyst to the reaction chamber; insert the carbon nanotube chemical vapor deposition catalyst between at least a portion of the stacked graphene sheets of the graphite substrate; and/or employ the heater and the temperature sensor to heat the carbon nanotube chemical vapor deposition catalyst in contact with the chemical vapor deposition feedstock provided by the gas source to a temperature selected to grow the carbon nanotubes. In some examples, the controller may be programmed to: grow the carbon nanotubes from the heated carbon nanotube chemical vapor deposition catalyst between the stacked graphene sheets of the graphite substrate for a period of time sufficient to separate at least a portion of the stacked graphene sheets of the graphite substrate using the carbon nanotubes; and/or employ the temperature sensor to monitor a reduction in temperature of the carbon nanotubes and the separated graphene sheets to provide the carbon nanotube-graphene composite.

Various examples of the carbon nanotube-graphene composites are described herein. In some examples, the carbon nanotube-graphene composites may include an array of stacked graphene sheets arranged in a substantially graphitic structure; and a collection of carbon nanotubes disposed between at least a portion of the stacked graphene sheets. In many examples, the carbon nanotubes may separate the portion of the stacked graphene sheets by a distance of at least about 10 nanometers.

Various example capacitor devices are described herein. In some examples, the capacitor devices may include: a first electrode; a second electrode; a first carbon nanotube-graphene composite conductively coupled to the first electrode; and/or a second carbon nanotube-graphene composite conductively coupled to the second electrode. In various examples of the capacitor devices, the first and second carbon nanotube graphene composites may each include an array of graphene sheets arranged in a substantially graphitic structure. In some examples of the capacitor devices, a collection of carbon nanotubes may be disposed between at least a portion of the stacked graphene sheets, and the carbon nanotubes may separate the portion of the stacked graphene sheets by a distance of at least about 10 nanometers.

### BRIEF DESCRIPTION OF THE DRAWINGS

The foregoing and other features of this disclosure will become more fully apparent from the following description and appended claims, taken in conjunction with the accompanying drawings. Understanding that these drawings depict only several embodiments arranged in accordance with the disclosure and are, therefore, not to be considered limiting of its scope, the disclosure will be described with additional specificity and detail through use of the accompanying drawings, in which:

FIG. 1 is a conceptual drawing that represents various capacitor devices that may include carbon nanotube-graphene composites;

FIG. 2 is a conceptual drawing that represents various example methods of making carbon nanotube-graphene composites;

FIG. 3 is a conceptual drawing that represents various example capacitor devices that may include one or more carbon nanotube-graphene composites as electrodes;

FIG. 4 is a graph that shows example Raman spectra and examples of D and G bands therein that may be employed to calculate a ratio of the D and G band intensities, represented by the I_{D}/I_{G} ratio, which may indicate the extent of graphite-like structures in various samples of carbon nanotube-graphene composites;

FIG. 5 is a block diagram that represents various examples automated machines that may be used in the various methods of making carbon nanotube-graphene composites:

FIG. 6 is a flow diagram showing example blocks that may be used in various example methods of making carbon nanotube-graphene composites;

FIG. 7 is a block diagram that illustrates various example computer program products that may be used to control the various automated machines of FIG. 5 or similar equipment in the various methods of making carbon nanotube-graphene composites; and

FIG. 8 is a block diagram that represents various general purpose computing devices that may be used to control the various automated machines of FIG. 5 or similar equipment in the various methods of making carbon nanotube-graphene composites;

all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to compositions, methods, apparatus, systems, devices, and/or computer program products related to manufacturing or using carbon nanotube-graphene composites, for example as electrodes that are part of an energy storage device such as capacitor devices. In various examples, the capacitor devices may be arranged as double layer capacitors, electrochemical double layer capacitors, pseudo-capacitors, and hybrid capacitor.

Briefly stated, technologies are described herein for various carbon nanotube-graphene composites. In some examples, the carbon nanotube-graphene composites may include an array of graphene sheets arranged in a substantially graphitic structure that may be separated by a collection of carbon nanotubes located between at least a portion of the graphene sheets. Various example capacitor devices are described that may include the carbon nanotube-graphene composites. Such capacitor devices may include two parallel electrodes, one or both of which may include the carbon nanotube-graphene composites. The space between the parallel electrodes may be contacted with one or more electrolytes or dielectric materials. Such capacitor devices may have high electrode surface area and may avoid pore effects, in comparison to high surface area porous electrodes without the carbon nanotube-graphene composite electrodes.

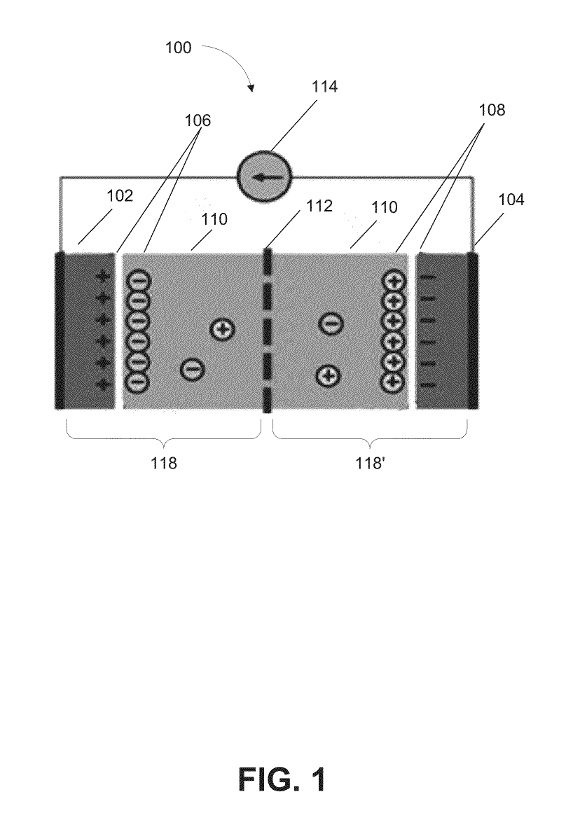

FIG. 1 is a conceptual drawing that represents various capacitor devices 100 that may include the carbon nanotube-graphene composites 118 and 118′, arranged in accordance with at least some embodiments described herein. In various examples, the capacitor devices 100 may include charge collection electrodes 102 and 104. The capacitor devices 100 may also include one or more electrochemical layers such as 106 and 108. The capacitor devices 100 may further include an ionic conductive electrolyte 110. The capacitor devices 100 may also include an ionic conductive/electrical insulator separator membrane 112. Collectively, the electrochemical double layer 106 and the ionic conductive electrolyte 110 may represent the carbon nanotube-graphene composite 118; and the electrochemical double layer 108 and the ionic conductive electrolyte 110 may represent the carbon nanotube-graphene composite 118′.

In various examples, the charge collection electrodes 102 and 104 may be coupled to an external circuit 114. In some examples of capacitor device 100, the charge collection electrodes 102 and 104 may include porous carbon and the ionic conductive electrolyte 110 may include ionic salts in solution. In many examples of capacitor device 100, the charge collection electrodes 102 and 104 may include conductive polymers or blends of conductive polymers and polymeric electrolytes. The conductive polymers or blends of conductive polymers and polymeric electrolytes may be configured as intermediate layers or as a redox based capacitor. The charge collection electrodes 102 and 104 may include conductive polymers or blends thereof. A polarization induced potential barrier may be formed 112 that permits spatial charge separation and may permit operation of the electrochemical double layers 106 and 108. In several examples of capacitor devices represented by capacitor device 100, the ionic conductive/electrical insulator separator membrane 112 may include an ionically conductive polymer.

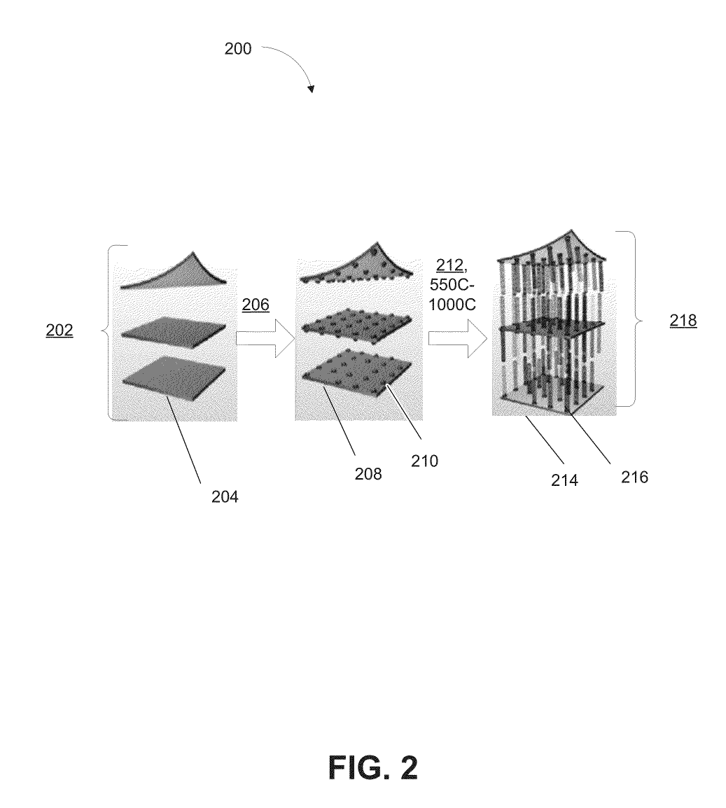

FIG. 2 is a conceptual diagram 200 that represents various methods of making the carbon nanotube-graphene composites, arranged in accordance with at least some embodiments described herein. In various examples, the methods represented by diagram 200 may include one or more operations such as: catalyst deposition, catalyst intercalation, catalyst nanoparticle formation, catalyzed chemical vapor deposition, and/or carbon nanotube growth to form the carbon nanotube-graphene composites.

In various examples of the methods illustrated by conceptual diagram 200, a carbon nanotube chemical vapor deposition catalyst or catalyst precursor 206 may be contacted to graphite 202. The catalyst or catalyst precursor 206 may intercalate between the graphene sheets 204. The catalyst or catalyst precursor 206 may be treated to form catalyst nanoparticles 210. The catalyst nanoparticles 210 may be located between the graphene sheets effective to form catalyst loaded graphene sheets 208. The catalyst loaded graphene sheets 208 may be contacted with a chemical vapor deposition feedstock at a temperature suitable for growing carbon nanotubes. The temperature may vary depending on the nature of the catalyst and the nature of the chemical vapor deposition feedstock. In various examples, suitable temperatures may be in a range from about 550° C. to about 1000° C. The carbon nanotubes 216 may grow between the catalyst loaded graphene sheets 208 during the CVD process, and may cause the graphene sheets 208 to separate to form carbon nanotube decorated graphene sheets 214. Collectively, the carbon nanotube decorated graphene sheets 214 may be referred to as carbon nanotube-graphene composite 218.

Conceptual diagram 200 depicts a portion of graphite 202 that may include graphene sheets 204. In some examples, the graphene sheets 204 may be at least partly arranged in stacked sheets. In FIG. 2, the graphene sheets 204 are depicted as separated for purposes of illustrating the concepts described herein.

In various examples, the carbon nanotube-graphene composite 218 may be cooled. In some examples, the carbon nanotube-graphene composite 218 may be further treated as desired before use, for example, by washing or oxidizing.

In several examples, the carbon nanotube-graphene composite 218 may be treated with acid, metal chelators, heat, oxygen, or oxidants. For example, the carbon nanotube-graphene composite 218 may be treated after cooling with one or more of hydrofluoric acid, hydrochloric acid, hydrobromic acid, hydroiodic acid, nitric acid, sulfuric acid, perchloric acid, a metal chelator, combinations thereof, and/or an aqueous solution thereof, followed by washing with distilled water to remove the acid and/or metal chelator.

In some examples, the carbon nanotube-graphene composite 218 may be treated by heating in a range from about 550° C. to about 1000° C. in the presence of oxygen. For example, after the chemical vapor deposition process is concluded, oxygen may be added for a period of time while the temperature may be maintained in a range from about 550° C. to about 1000° C. In further examples, the carbon nanotube-graphene composite 218 may be treated after cooling with an aqueous solution of one or more of bromine, potassium permanganate, and/or hydrogen peroxide, followed by washing with distilled water.

As used herein, a “carbon nanotube” may refer to cylindrical form of graphene having single or multiple walls. The carbon nanotubes described herein may be characterized by a dimensional constraint such as length, width, diameter, etc. In some examples, the carbon nanotubes may be characterized by a diameter in a range from about 1 nanometer to about 200 nanometers, or in several examples, a diameter in a range from about 1 nanometer to about 50 nanometers. Such carbon nanotubes may be conductive or may have a conductive state, or may be semiconductive or have a semiconducting state. Suitable carbon nanotubes may include a multi-walled carbon nanotube (MWCNT) or a single-walled carbon nanotube (SWCNT).

In several examples, carbon nanotubes may be suitable for capacitor devices described herein for any one or more of the following reasons. (1) Carbon nanotubes may be highly conductive of electricity, which may permit the nanotubes to be effective even when long compared to their diameters. (2) Carbon nanotubes may be very small in diameter, on the order of 1-4 nanometers for some single walled carbon nanotubes. Such carbon nanotube diameters may permit close packing, large surface area, and/or high charge density when included in the capacitor device examples described herein. (3) Carbon nanotubes may be mechanically strong, which may allow them to separate the graphene sheets by growing, yet breakage may be avoided.

As used herein, the term “growing” the nanotubes may mean contacting a suitable nanoparticle catalyst with a suitable chemical vapor deposition feedstock so that nanotubes may be grown from the nanoparticle catalyst. In some examples, the carbon nanotubes may grow to extend from the nanoparticle catalyst as a base, or, the carbon nanotubes may grow from the tip of the nanotube, such that the nanoparticle catalyst may be located at the tip of at least some of the growing carbon nanotubes.

In various examples, suitable nanoparticle catalysts for carbon nanotubes may include, e.g., nanoparticles of substantially the same size as the desired nanotube. Suitable metals for nanoparticle catalysts may include one or more of: Al, Mg, Sc, Ti, V, Cr, Mn, Fe, Co, Ni, Cu, Zn, Y, Zr, Nb, Mo, Tc. Ru, Rh, Pd, Ag, Cd, Lu, Hf, Ta, W, Re, Os, Ir, Pt, Au, or Hg, provided that the nanoparticle catalyst may be a solid under the temperature conditions of the nanotube growth process. Suitable catalyst precursors may include salts or complexes of one or more of the metals with inorganic or organic ligands, which may be neutral or anionic. For example, inorganic ligands may include fluoride, chloride, bromide, iodide, oxo, hydroxyl, sulfide, azide, nitrite, nitrate, NO, ammonia, chlorate, perchlorate, bromate, perbromate, iodate, periodate, sulfate, sulfite, persulfate, oxo, water, combinations thereof, and the like. Organic ligands may include, for example, CO, CO₂, acetate, oxalate, CN, cyanate, isocyanates, thiocyanate, isothiocyanate, acetonitrile, pyridyl, ethylene diamine, diethylene triamine, triethylene tetramine, 2,2′-bipyrididine, 1,10-phenanthroline, triphenylphosphine, acetylacetonate, alkenes, benzene, 1,2-bis(diphenylphosphino)ethane, 1,1-bis(diphenylphosphino)methane, cyclopentadienyl, dimethylglyoximate, ethylenediaminetetraacetate, ethylenediaminetriacetate, glycinate, pyrazinyl, triazacyclononyl, terpyridyl, tricyclohexylphosphine, trimethylphosphine, tri(o-tolyl)phosphine, tris(2-aminoethyl)amine, tris(2-diphenylphosphineethyl)amine, terpyridine, tropylium, combinations thereof, or the like. Suitable catalyst precursors may also include the metals themselves.

In various examples, a suitable nanoparticle catalyst precursor may include FeCl₃. Graphite 202 may be contacted with a solution of FeCl₃ in an organic solvent, for example, ethanol, methanol, diethyl ether, benzene, toluene, or the like. The FeCl₃ may intercalate between graphene sheets 204 of graphite 202. The solvent may be removed, and the graphite/FeCl₃ may be calcined in the presence of a gaseous chemical reductant, e.g., H₂, to produce catalyst loaded graphene sheets 208 containing the Fe nanoparticle catalysts 210. Other chemicals, such as CoCl₂, may also be used for this purpose. The graphite, which is loaded with FeCl₃ or CoCl₂, may be reduced at 600-800° C. under 3-7% H₂/Ar flow for 4-12 hours.

In various examples, suitable growth conditions for carbon nanotubes from such nanoparticle catalysts may include various pressures and temperatures, as well as various process feedstocks and chemical vapor deposition feedstocks. In some examples, chemical vapor deposition (CVD) conditions may include atmospheric or reduced pressure. In various examples, CVD conditions may include heating the nanoparticle catalyst, graphite, and chemical vapor deposition feedstock, e.g. from room temperature to about 1000 degrees Celsius. The CVD conditions may also include heating in a range from about 550 to about 1000 degrees Celsius, or in other examples, the CVD conditions may include heating in a range from about 650 to about 750 degrees Celsius.

As used herein, a “chemical vapor deposition feedstock” may be any organic compound which forms a chemical vapor under the CVD conditions that may be suitable for growing carbon nanotubes from the selected nanoparticle catalysts. In several examples, suitable carbon-containing chemical vapor deposition feedstocks may include one or more of: CO; CO₂; alkanes, e.g., methane, ethane, acetylene, propane, butane, pentane, cyclobutane, cyclopropane, or cyclohexane; alkenes, e.g., ethylene, propene, or butene; organic solvents, e.g., methanol, ethanol, diethyl ether, benzene, toluene, or xylene; organic molecules, e.g., camphor; pyrolyzable or vaporizable complex organic mixtures, e.g., extracts of coal or petroleum; and/or pyrolyzable or vaporizable bioderived carbon sources, e.g., cellulose or plant oils.

In various examples, suitable CVD conditions may also include injection of one or more process gases or vapors into the CVD feedstock, such as one or more of: water, hydrogen, nitrogen, ammonia, helium, neon, argon, krypton, and/or xenon.

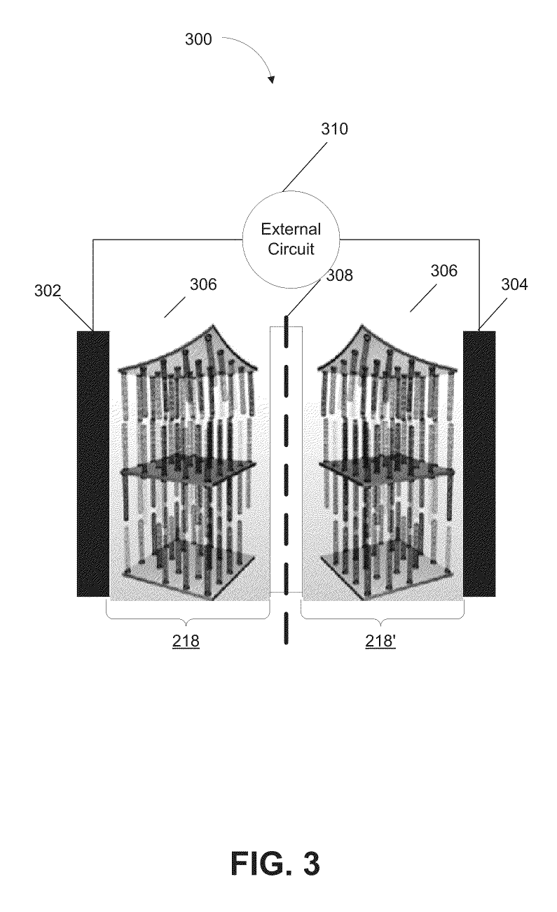

FIG. 3 is a conceptual drawing 300 that represents various example capacitor devices that may include electrodes made from the carbon nanotube-graphene composites, arranged in accordance with at least some embodiments described herein. In various examples, the capacitor devices represented by drawing 300 may include discrete laminated layers involving charge collection electrodes 302 and 304, carbon nanotube-graphene composite layers 218 and 218′, conductive electrolyte 306, and ionic conductive/electrical insulator separator membrane 308.

In some examples, the charge collection electrodes 302 and 304 may be coupled to an external circuit 310, which may be any suitable circuit connected to the capacitor device 300. Carbon nanotube-graphene composite layers 218 and 218′ are illustrated conceptually in FIG. 3, and are not to be limited by the orientation illustrated. In various examples, the charge collection electrodes 302 and 304 may be the carbon nanotube-graphene composite layers 218 and 218′, respectively. In some examples, the charge collection electrodes 302 and 304 may be made of any suitable conducting material such as metals or alloys thereof, conductive polymers, conducting oxides, or the like. In several examples, charge collection electrodes 302 and 304 may include metals or alloys that may include one or more metals such as: copper, aluminum, tin, lead, iron, chromium, cobalt, nickel, silver, gold, platinum, palladium, vanadium, manganese, titanium, tungsten, indium, zinc, and/or cadmium. In many examples, the charge collection electrodes 302 and 304 may be in the form of a sheet, wire, plate, foil, or tape. In multiple examples, the charge collection electrodes 302 and 304 may include conducting oxides such as indium tin oxide, aluminum doped zinc oxide, or indium doped cadmium oxide.

In various examples, the charge collection electrodes 302 and 304 may include a conducting polymer, for example: a polyacetylene, a polyarylene (e.g., poly-para-phenylene), a polyheteroarylene (e.g., polypyrrole, polypyridine, or the like), a polyvinylarylene (e.g., poly-para-phenylenevinylene), a polyvinylheteroarylene (e.g., polythiophene vinylene), a polyarylene ethynylene (e.g., poly-para-phenylene ethynylene), a polyheteroarylene ethynylene (e.g. polypyridine ethynylene), a combination thereof, and/or a copolymer thereof. In some examples, the conductive polymer may include: a polyacetylene, a poly(phenylene vinylene), a poly(fluorene), a polypyrene, a polyazulene, a polynaphthalene, a poly(pyrrole), a polyindole, a polyazepine, a polyaniline, a polypyridine, a poly(thiophene), a poly(thiophene vinylene), a poly(phenylene sulfide), a combination thereof, and/or a copolymer thereof.

In various examples, the charge collection electrodes 302 and 304 and the respective carbon nanotube-graphene composite layers 218 and 218′ may be separated by an ionically conducting, electrically insulating electrolyte membrane 308. The electrolyte membrane 308 may include, for example: a poly(oxy)alkylene, a polytetrafluoroethylene:perfluorosulfonic acid copolymer, a sulfonated arylene, a sulfonated polystyrene, a sulfonated poly(tetrafluoroethylene-hexafluoropropylene), a poly(vinylidene fluoride), a sulfonated poly(aryl)siloxane, a sulfonated poly(alkyl)siloxane, a sulfonated polyetheretherketone, a sulfonated polysulfone, a sulfonated polyethersulfone, a polybenzimidazole, a polyimide, a polyphenylene, a poly(4-phenoxybenzoyl-1,4-phenylene), a polybenzimidazole, a polyvinyl alcohol, a polyacrylamide, a polyethylenimine, a combination thereof, and/or any other ionically conducting, electrically insulating electrolyte membrane suitable for use in a capacitor. In particular, the electrolyte membrane 306 may include a salt of an ionomer, a polymer that may include both electrically neutral repeat units and ionizable repeat units. Suitable neutral repeat units may include alkyl, alkyl ether, perfluoroalkyl, and/or perfluoroalkyl ether units. Suitable ionizable repeat units may include sulfonates, phosphates, and/or carboxylates. Many suitable ionomers are commercially available and may be commonly employed as proton exchange membranes. In various examples, suitable ionomers may include the class of polytetrafluoroethylene:perfluorosulfonic acid copolymers known by the trade name NAFION® (Dupont, Wilmington, Del.). These ionomers may be characterized by a polytetrafluoroethylene backbone substituted with perfluorovinyl ether groups having a terminal sulfonate. One example is tetrafluoroethylene-perfluoro-3,6-dioxa-4-methyl-7-octenesulfonic acid copolymer (CAS Reg. No. 66796-30-3, “NAFION®-H”).

In various examples, the conductive electrolyte 306 may include one or more electrolyte salts. Suitable electrolyte salts may include positively charged cations, e.g., an alkali metal cation, an alkaline earth metal cation, or a mixture thereof. In various examples, suitable alkali metals for cations may include: lithium, sodium, potassium, rubidium, caesium, and/or francium. In various examples, suitable alkali earth metals for cations may include: beryllium, magnesium, calcium, strontium, and/or barium. Suitable cations for electrolyte salts may include other cations, such as: ammonium, tetraalkylammonium, phosphonium, tetralkylphosphonium, and/or a combination thereof. Suitable electrolyte salts may include negatively charged anions such as: fluoride, chloride, bromide, iodide, carboxylates, trifluoromethanesulfonate, bistrifluoromethanesulfonimidate, fluorosulfate, hexafluorophosphate, perchlorate, tetrafluoroborate, p-toluenesulfonate, p-bromobenzenesulfonate, 2- or 4-nitrobenzenesulfonate, methanesulfonate, trifluoromethanesulfonate, 5-(dimethylamino)naphthalene-1-sulfonate, nitrate, and/or combinations thereof. Suitable carboxylates may include, e.g., acetate, and/or benzoate. In some examples, the electrolyte salt may include perchlorate or trifluoromethansulfonate anions.

In various examples, the conductive electrolyte 306 may be provided in a suspension or a solution as a liquid electrolyte. In some examples, the liquid electrolyte may include: a polyoxyalkylene, a polyoxyalkylene alcohol, an alkyl ether, a cycloalkyl ether, an alkylene carbonate, a cycloalkylene carbonate, an alkanone, a cycloalkanone, a lactone, and/or a combination thereof. Suitable polyoxyalkylene or polyoxyalkylene alcohols may include, e.g.: polyethylene oxide and/or polyethylene glycol. Suitable alkyl ethers may include, e.g.: diethyl ether, and/or diisopropyl ether. Suitable cycloalkyl ethers may include, for example: tetrahydrofuran and/or dioxane. Suitable alkylene or cycloalkylene carbonates may include: ethylene carbonate and/or propylene carbonate. Suitable alkanones or cycloalkanones may include, e.g.: acetone, methyl ethyl ketone, cyclopentanone, and/or cyclohexanone. Suitable lactones may include beta-propiolactone, gamma-butyrolactone, and/or delta-valerolactone.

In further examples, the conductive electrolyte 306 may include an ionic liquid. Suitable cations for the ionic liquid electrolyte include, for example: 1,3-dialkyl imidazoliums. N-alkyl pyridiniums, N,N-dialkyl pyrrolidiniums, alkyl phosphoniums, alkyl ammoniums, and/or alkyl sulfoniums. Specific examples of cations for the ionic liquid electrolyte may include: 1-butyl-3-methylimidazolium, 1-butylpyridinium, N-methyl-N-butyl pyrrolidinium, and/or tetrabutylammonium. Suitable anions for the ionic liquid electrolyte may include, for example: fluoride, chloride, bromide, iodide, carboxylates, trifluoromethanesulfonate, bistrifluoromethanesulfonimidate, fluorosulfate, hexafluorophosphate, perchlorate, tetrafluoroborate, p-toluenesulfonate, p-bromobenzenesulfonate, 2- or 4-nitrobenzenesulfonate, methanesulfonate, trifluoromethanesulfonate, 5-(dimethylamino)naphthalene-1-sulfonate, and/or nitrate. Suitable carboxylates may include, e.g., acetate and/or benzoate. In some examples, the electrolyte salt may include perchlorate and/or trifluoromethansulfonate anions. Specific examples of ionic liquid electrolytes include, but are not limited to: 1-butyl-2,3-dimethylimidazolium tetrafluoroborate, 1-butyl-1-methylpyrrolidinium bis(trifluoromethyl sulfonyl)imide, 1-dodecyl-3-methylimidazolium iodide, 1-ethyl-2,3-dimethylimidazolium trifluoromethane sulfonate, 1-ethyl-3-methylimidazolium dicyanamide, 1-ethyl-3-methylimidazolium nitrate, 1-ethyl-3-methylimidazolium tetrafluoroborate, 1-ethyl-3-methylimidazolium thiocyanates, sulfonate, 1-ethyl-3-methylimidazolium trifluoromethane sulfonate, methyl-trioctylammonium bis(trifluoromethyl sulfonyl)imide, tetrabutylammonium bis(trifluoromethylsulfonyl)imide, tetraethylammonium trifluoromethanesulfonate, triethylsulfonium bis(trifluoromethylsulfonyl)imide, tetrabutylammonium bromide, tetrabutylphosphonium tetrafluoroborate, 1-butyl-3-methylimidazolium bis(trifluoromethyl sulfonyl)imide, 1-butyl-3-methylpyridinium bis(trifluoromethylsulfonyl)imide, 1,2-dimethyl-3-propylimidazolium bis(trifluoromethylsulfonyl)imide, 1,2-dimethyl-3-propylimidazolium tris(trifluoromethylsulfonyl)methide, 1-ethyl-3-methylimidazolium bis(pentafluoroethylsulfonyl)imide, 1-ethyl-3-methylimidazolium bis(trifluoromethylsulfonyl) imide, and/or 3-methyl-1-propylpyridinium bis(trifluoromethylsulfonyl)imide (obtainable from, e.g., Sigma-Aldrich, St. Louis, Mo.).

In various examples, the carbon nanotube-graphene composite 218 may be characterized in part as an array of stacked graphene sheets arranged in a substantially graphitic structure. The various example processes and methods described herein for preparing carbon nanotube-graphene composite 218 may lend the graphitic structure of the graphite precursor 202 to the carbon nanotube-graphene composite 218. By growing nanotubes 216 between the graphene sheets and causing the graphene sheets to separate in forming composite 218, the carbon nanotube functionalized sheets 214 may retain some of the graphitic organization of the graphite precursor 202. In various examples, the extent of graphitic order or disorder in carbon nanotube-graphene composite 218 may be measured by Raman spectroscopy.

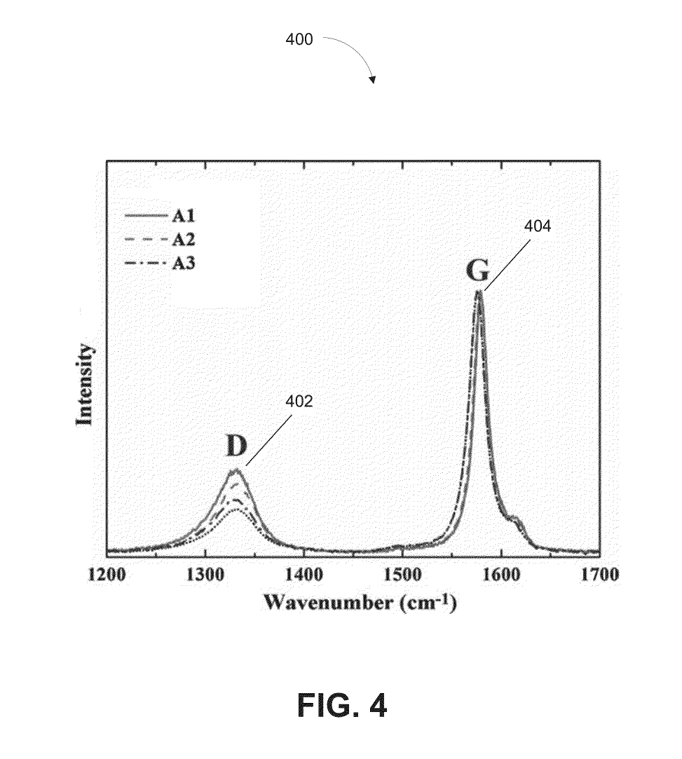

For example, FIG. 4 shows an example Raman spectra 400 of the D band 402 and G band 404 which may be employed to calculate a ratio of the peak intensity of the D band to the peak intensity of the G band, which may be referred to as the peak intensity ratio I_{D}/I_{G}.

In various examples, the peak intensity ration I_{D}/I_{G} may be indicative of the extent of graphite-like structure in a sample arranged in accordance with at least some embodiments described herein. The peak intensity ratio I_{D}/I_{G} may be employed to assess the extent of structural disorder in graphite and the size of graphitic domains. For example, the peak intensity ratio I_{D}/I_{G} is reportedly zero for a perfect, infinite graphene layer. By contrast, the peak intensity ratio I_{D}/I_{G} for a disordered sample of graphene oxide may be about 1 or higher.

The D band in graphene has been commonly reported at a wavenumber of about 1350 cm-1 corresponding to the A_{1g} vibrational mode and has been attributed to the breathing motion of sp2 hybridized carbon atoms in rings at edge planes and defects in graphene sheets. The G band in graphene has been commonly reported at a wavenumber of about 1580 cm-1 corresponding to the E_{2g} vibrational mode and has been attributed to the relative motion of sp2 hybridized carbon atoms in chains and rings.

As used herein, a “substantially graphitic structure” may mean that the carbon nanotube-graphene composite 218 may be characterized by a peak intensity ratio I_{D}/I_{G} of less than about 0.7. In various examples, the carbon nanotube-graphene composite 218 may be characterized by a peak intensity I_{D}/I_{G} ratio of: less than about 0.7, 0.6, 0.5, 0.4, 0.3, 0.2, or 0.1. In various examples, the peak intensity ration I_{D}/I_{G} of example carbon nanotube-graphene composites may be in a range from about zero to about 0.7, 0.6, 0.5, 0.4, 0.3, 0.2, or 0.1. In some examples, the peak intensity ratio I_{D}/I_{G} ratio of various example carbon nanotube-graphene composites may be in a range from about 0.1 to about 0.7, 0.6, 0.5, 0.4, 0.3, or 0.2.

In various examples, the carbon nanotube-graphene composite 218 may be characterized in part as an array of stacked graphene sheets arranged in a substantially graphitic structure; and a collection of carbon nanotubes disposed between at least a portion of the stacked graphene sheets, the carbon nanotubes may separate the portion of the stacked graphene sheets. As used herein, “separate” may mean that the carbon nanotubes are located between at least a portion of the graphene sheets in such a way as to keep the graphene sheets apart, in contrast to the mutual contact between graphene sheets as may be found in graphite. e.g., graphite 202. In various examples, the carbon nanotubes may separate the portion of the stacked graphene sheets by an average distance of at least about 10, 25, 50, 75, 100, 125, 150, 175, or 200 nanometers. In some examples, the separation of the stacked graphene sheets may be in a range from: about 10 nanometers to about 2 millimeters; about 100 nanometers to about 1 millimeter; about 100 nanometers to about 100 micrometers; or about 1 micrometer to about 1 millimeter.

The carbon nanotube-graphene composite 218 may be characterized in part by graphene oxide content as a percentage of total weight. In various examples, the carbon nanotube-graphene composite may include a graphene oxide content percentage by weight of less than about 20, 10, 5, 2.5, 1, 0.5, 0.4, 0.3, 0.2, or 0.1%. The carbon nanotube-graphene composite 218 may be characterized in part by elemental composition, for example, oxygen elemental content as a percentage of total weight. In many examples, the carbon nanotube-graphene composite may include an oxygen elemental content as a percentage of total weight of less than about 20, 10, 5, 2.5, 1, 0.5, 0.4, 0.3, 0.2, or 0.1%. In some examples, the described composites may be obtained without an oxidation process. In several examples, the described composites may be obtained without a process of reducing graphene oxide to form reduced graphene oxide.

In various examples, the carbon nanotube-graphene composite 218 may be characterized in part by elemental composition, for example, metal elemental content as a percentage of total weight. In some examples, the carbon nanotube-graphene composite may include a total metal elemental content as a percentage of total weight of less than about 20, 10, 5, 2.5, 1, 0.5, 0.4, 0.3, 0.2, or 0.1%. In several examples, the carbon nanotube-graphene composite may include a total cobalt elemental content as a percentage of total weight of less than about 20, 10, 5, 2.5, 1, 0.5, 0.4, 0.3, 0.2, or 0.1%.

In various examples, the carbon nanotube-graphene composite 218 may be characterized in part by an average separation between the carbon nanotubes on each carbon-nanotube functionalized graphene sheet, the average separation being parallel to the plane of the graphene sheet. In various examples, the average separation between the carbon nanotubes on each carbon-nanotube functionalized graphene sheet may be in a range from: about 1 nanometer to about 1 micrometer; about 1 nanometer to about 500 nanometers; about 1 nanometer to about 100 nanometers; about 1 nanometer to about 50 nanometers; about 5 nanometers to about 100 nanometers; or about 5 nanometers to about 50 nanometers.

In various examples, the carbon nanotube-graphene composite 218 may be characterized in part by an average number density of carbon nanotubes on each carbon-nanotube functionalized graphene sheet. In some examples, the average number density of carbon nanotubes on each carbon-nanotube functionalized graphene sheet may be in a range from: about 400 carbon nanotubes per square micrometer of graphene to about 200000 carbon nanotubes per square micrometer of graphene; about 1000 carbon nanotubes per square micrometer of graphene to about 200000 carbon nanotubes per square micrometer of graphene; or about 2000 carbon nanotubes per square micrometer of graphene to about 200000 carbon nanotubes per square micrometer of graphene.

In various examples, the carbon nanotube-graphene composite 218 may be characterized in part by an average length of the carbon nanotubes. In some examples, the average length of the carbon nanotubes may be in a range from: about 10 nanometers to about 2 millimeters; about 100 nanometers to about 1 millimeter; about 100 nanometers to about 100 micrometers; or about 1 micrometer to about 1 millimeter.

In various examples, the carbon nanotube-graphene composite 218 may be characterized in part by a maximum mass specific capacitance at a temperature of about 25° C. as measured by chronopotentiometry in 6 Molar aqueous sodium hydroxide at a scan rate of 10 millivolts per second. The mass specific capacitance Cₘₛₚ may be measured by chronopotentiometry according to Equation [1]:

Cₘₛₚ=I/[(dV/dt)×m]

where I is the constant discharging current, dV/dt indicates the rate of voltage discharge versus time, and m is the mass of the corresponding carbon nanotube-graphene composite sample being tested. Under the preceding conditions, the maximum mass specific capacitance of the carbon nanotube-graphene composite in Farads per gram may be at least about 390, 400, 410, 420, 430, 440, or 450.

In various examples, the carbon nanotube-graphene composite 218 may be characterized in part by surface area per gram. In various examples, the surface area in square meters per gram of the carbon nanotube-graphene composite may be at least about 625, 650, 675, 700, 800, 900, or 1000. The specific surface area in square meters per gram of the carbon nanotube-graphene composite may be determined by physical adsorption of dry nitrogen and by calculating the amount of nitrogen corresponding to a monomolecular layer on the adsorbing surface of the carbon nanotube graphene composite. The amount of gas adsorbed can be measured by a volumetric or continuous flow procedure. The Brunauer-Emmett-Teller (BET) method for characterizing surface area of porous solids includes measuring nitrogen adsorption/desorption isotherms at 77 K and relative pressures (P/P₀) ranging from 0.05-1.0 may be defined by Equation [2]:

$$\frac{1}{[ {V}_{a} ( \frac{{P}_{0}}{P} - 1 ) ]} = \frac{C - 1}{{V}_{m} C} \times \frac{P}{{P}_{0}} + \frac{1}{{V}_{m} C}$$

where P=partial vapor pressure in pascals of adsorbate gas in equilibrium with the surface at 77.4 K; P₀=saturated pressure of adsorbate gas, in pascals; Vₐ=milliliter volume of gas adsorbed at 273.15 K and 1.013×10⁵ Pascals; Vₘ=milliliter volume of gas adsorbed at STP to produce an apparent monolayer on the sample surface; C=dimensionless constant that is related to the enthalpy of adsorption of the nitrogen. A value of Vₐ is measured at each of at least 3 values of P/P₀.
The left hand side of equation [2] may be plotted against P/P₀ according to the right hand side of Equation [2] to yield a straight line in the approximate relative pressure range P/P₀ of about 0.05 to 0.3. The squared correlation coefficient r² for a plot of the left hand side and the right hand side of Equation [2] may be at least about 0.995. The resulting plot may be evaluated by linear regression analysis, from which Vₘ may be calculated as 1/(slope+intercept), and C may be calculated as (slope/intercept)+1. From the value of Vₘ, the specific surface area, S, in square meters per gram may be calculated by Equation [3]:

$$S = \frac{{V}_{m} Na}{m \times 22400}$$

where N=Avogadro's number; a=1.62×10⁻¹⁹ square meters, the approximate effective cross-sectional area of one nitrogen molecule; m=mass of carbon nanotube-graphene composite sample, in grams; and 22400=milliliter volume occupied by 1 mole of the nitrogen adsorbate gas at 273.15 K and 1.013×10⁵ Pascals.

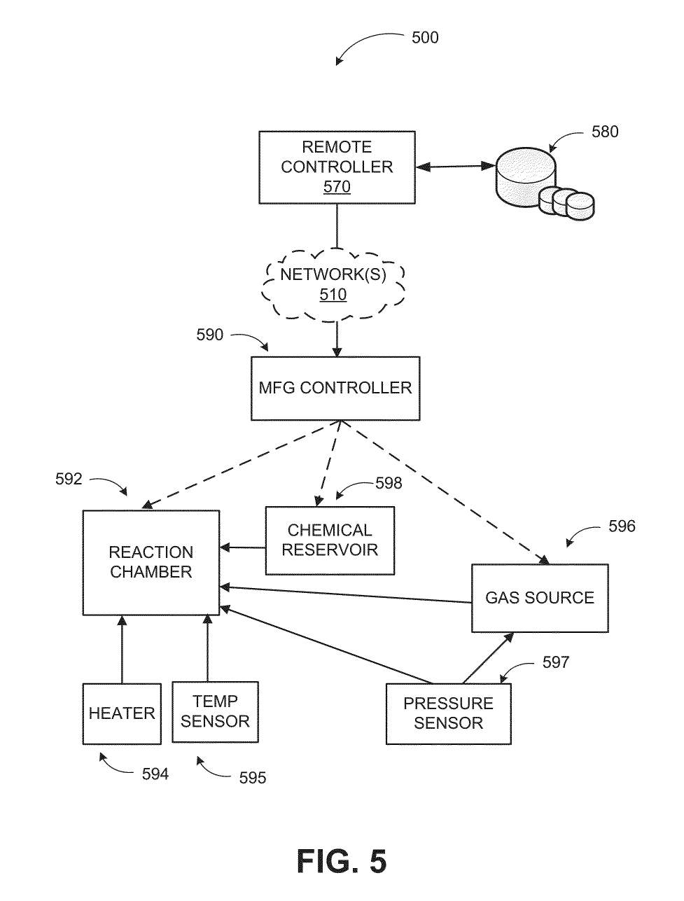

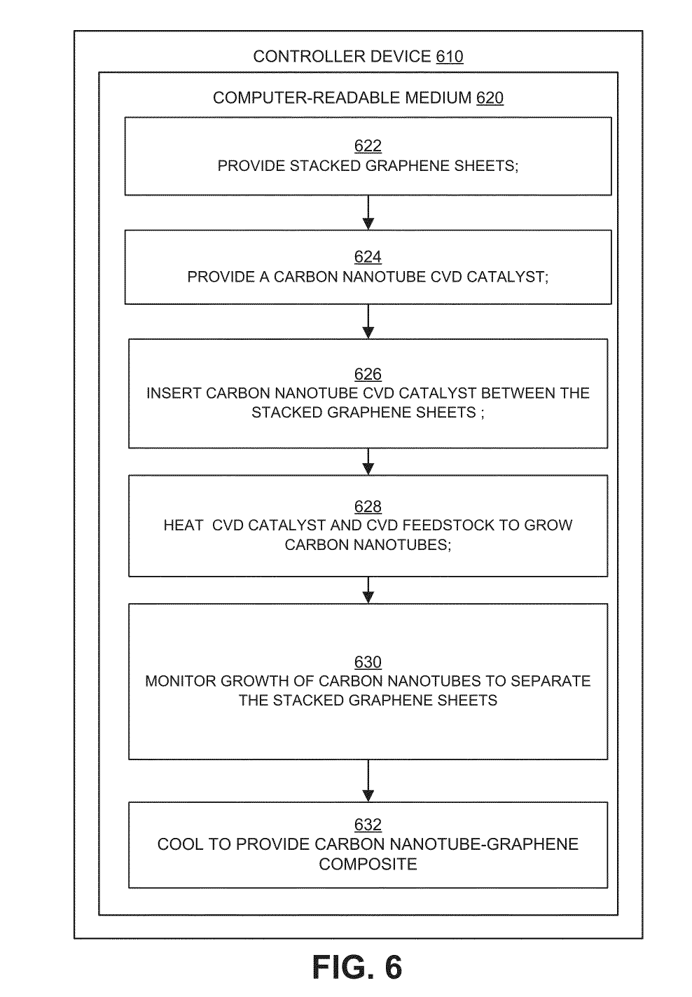

FIG. 5 is a block diagram of an automated machine that may be used for making an example capacitor device using the process steps outlined in FIG. 6, arranged in accordance with at least some embodiments described herein.

As illustrated in FIG. 5, a manufacturing controller 590 may be coupled to machines that can be used to carry out the steps described in FIG. 6, for example, a reaction chamber 592, for growing the nanotubes, which may be equipped, for example, with heater 594, temperature sensor 595, chemical vapor deposition features, gas/vacuum inlets, and so on; a chemical reservoir 598 configured to provide catalyst or catalyst precursor 206 in the form of a liquid, solution, suspension, or vapor; gas source 596, configured to provide chemical vapor deposition feedstock and other process gases which may be employed, as described herein; and temperature sensor 597. For example, manufacturing controller 590 may be configured for operation by human control, or may be directed by a remote controller 570 via network 510. Data associated with controlling the different processes of forming a capacitor device may be stored at and/or received from data stores 580.

Example embodiments may also include methods for forming example carbon nanotube-graphene composites. These methods can be implemented in any number of ways, including the systems described herein. One such way may be by machine operations, of devices of the type described in the present disclosure. Another optional way may be for one or more of the individual operations of the methods to be performed in conjunction with one or more human operators performing some of the operations while other operations may be performed by machines. These human operators need not be collocated with each other, but each can be separately with a machine that performs a portion of the program. In other examples, the human interaction can be automated such as by pre-selected criteria that may be machine automated.

FIG. 6 is a flow diagram showing steps that may be used in forming an example carbon nanotube-graphene composite in accordance with at least some embodiments described herein. Example methods may include one or more operations, functions or actions as illustrated by one or more of blocks 622, 624, 626, 628 and/or 630. The operations described in the blocks 622 through 630 may also be stored as computer-executable instructions in a computer-readable medium such as a computer-readable medium 620 of a computing device 610.

In various examples, a method of forming a carbon nanotube-graphene composite may begin with block 622, “PROVIDE STACKED GRAPHENE SHEETS”. Stacked graphene sheets may be provided as part of a graphite substrate. Block 622 may be performed, for example, by manually or automatically causing a sample such as graphite substrate 202 to be loaded into a reaction chamber such as reaction chamber 592 of FIG. 5.

Block 622 may be followed by block 624, “PROVIDE A CARBON NANOTUBE CVD CATALYST”. At block 624, manufacturing controller 590 may be configured to instruct chemical reservoir 598 to contact graphite substrate 202 with a catalyst or catalyst precursor such as 206.

Block 624 may be followed by block 626, “INSERT CARBON NANOTUBE CVD CATALYST BETWEEN THE STACKED GRAPHENE SHEETS”. At block 626, catalyst or catalyst precursor 206 may be in the form of a suspension, solution, liquid or vapor. Catalyst or catalyst precursor 206 may intercalate between the graphene sheets in graphite substrate 202 to contact graphene sheet 204 to form catalyst loaded graphene sheet 208. When 206 is a catalyst precursor, an optional step of heating in the presence of a gaseous chemical reductant, e.g., hydrogen or other reducing gas, may be conducted, to convert catalyst precursor 206 into nanoparticle catalyst 210. Heating may be provided by heater 594 and controlled with the aid of temperature sensor 595. The gaseous chemical reductant may be provided using gas source 596 and controlled with the aid of pressure sensor 597.

Block 626 may be followed by block 628, “HEAT CVD CATALYST AND CVD FEEDSTOCK TO GROW CARBON NANOTUBES”. At block 626, heater 594 may be employed to heat the graphite substrate 202 and the catalyst in the reaction chamber 592 to a temperature suitable for growing carbon nanotubes. The temperature for growing carbon nanotubes may depend on the catalyst used, the chemical vapor deposition feedstock used, the pressure, the growth rate desired, particulars of a specific reaction chamber, and the like. The temperature for growing the carbon nanotubes may be in a range from about 550° C. to about 1000° C., and may be held at such temperature as long as desired nanotube growth is observed.

Block 628 may be followed by block 630, “MONITOR GROWTH OF CARBON NANOTUBES TO SEPARATE THE STACKED GRAPHENE SHEETS”. Growth of carbon nanotubes to separate the stacked graphene sheets may be provided by any suitable means, for example, by observing the expansion of the graphite substrate 202 as the growing nanotubes separate the graphene sheets within.

Block 630 may be followed by block 632, “COOL TO PROVIDE CARBON NANOTUBE-GRAPHENE COMPOSITE”. In block 630, the CVD deposition chamber may be allowed to cool simply by turning the heater off, or may be actively cooled by external means under a desired temperature profile, for example, by directing a stream of a cooling gas, such as nitrogen, helium, neon, or argon from gas source 596.

The blocks included in the process of FIG. 6 described above are for illustration purposes. A process of forming an example capacitor device as described herein may be implemented by similar processes with fewer or additional blocks. In some examples, the blocks may be performed in a different order. In some other examples, various blocks may be eliminated. In still other examples, various blocks may be divided into additional blocks, or combined together into fewer blocks. Although illustrated as sequentially ordered blocks, in some implementations the various blocks may be performed in a different order, or in some cases various blocks may be performed at substantially the same time.

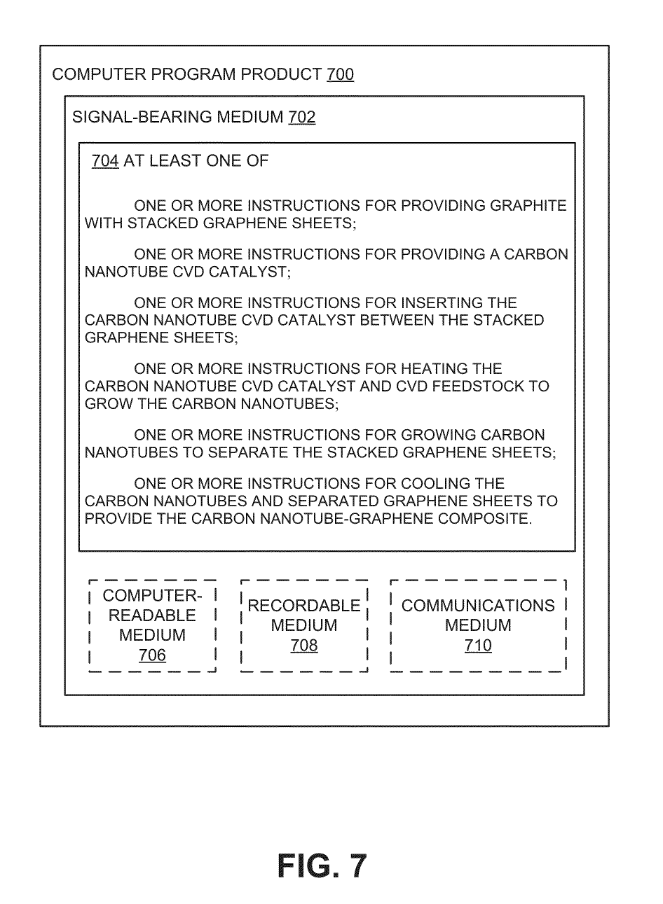

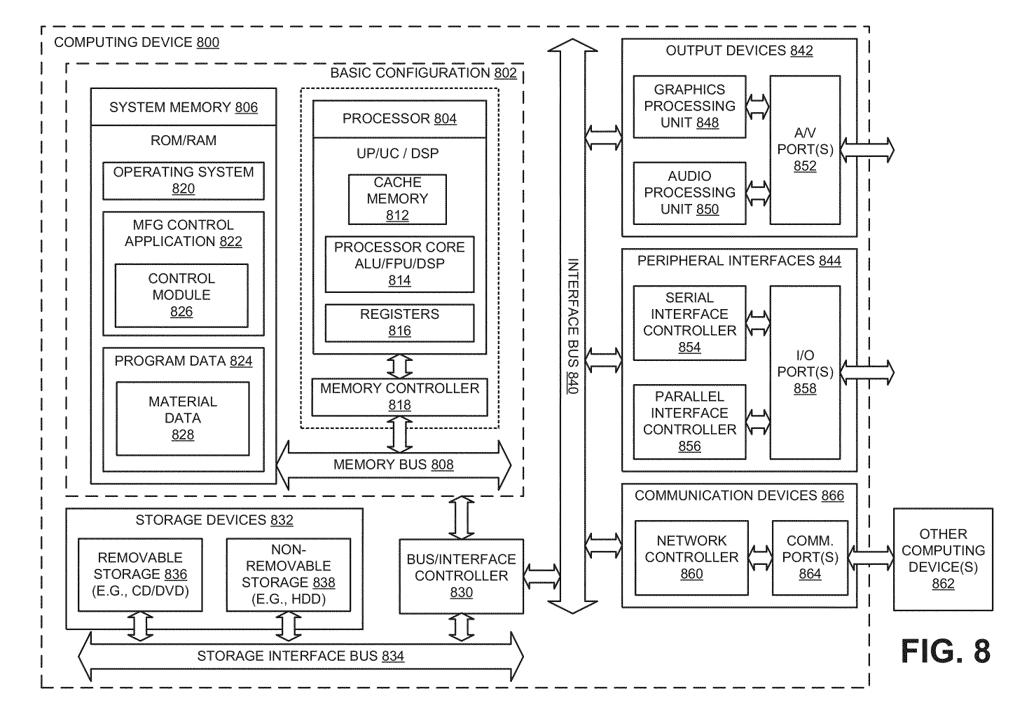

FIG. 7 illustrates a block diagram of an example computer program product that may be used to control the automated machine of FIG. 5 or similar manufacturing equipment in making an example electrochemical capacitor, in accordance with at least some embodiments described herein. In some examples, as shown in FIG. 7, computer program product 700 may include a signal bearing medium 702 that may also include machine readable instructions 704 that, when executed by, for example, a processor, may provide the functionality described above with respect to FIG. 5, FIG. 6, and FIG. 8. For example, referring to processor 590, one or more of the tasks shown in FIG. 7 may be undertaken in response to instructions 704 conveyed to the processor 590 by medium 702 to perform actions associated with making an example electrochemical capacitor as described herein. Some of those instructions may include, for example, one or more instructions for: “PROVIDING GRAPHITE WITH STACKED GRAPHENE SHEETS”; “PROVIDING A CARBON NANOTUBE CVD CATALYST”; “INSERTING THE CARBON NANOTUBE CVD CATALYST BETWEEN THE STACKED GRAPHENE SHEETS”; “HEATING THE CARBON NANOTUBE CVD CATALYST AND CVD FEEDSTOCK TO GROW THE CARBON NANOTUBES”; “GROWING CARBON NANOTUBES TO SEPARATE THE STACKED GRAPHENE SHEETS”; and “COOLING THE CARBON NANOTUBES AND SEPARATED GRAPHENE SHEETS TO PROVIDE THE CARBON NANOTUBE-GRAPHENE COMPOSITE.” In some implementations, signal bearing medium 702 depicted in FIG. 7 may encompass a computer-readable medium 706, such as, but not limited to, a hard disk drive, a Compact Disc (CD), a Digital Versatile Disk (DVD), a digital tape, memory, etc. In some implementations, signal bearing medium 902 may encompass a recordable medium 708, such as, but not limited to, memory, read/write (R/W) CDs, R/W DVDs, etc. In some implementations, signal bearing medium 702 may encompass a communications medium 710, such as, but not limited to, a digital and/or an analog communication medium (e.g., a fiber optic cable, a waveguide, a wired communications link, a wireless communication link, etc.). For example, computer program product 700 may be conveyed to the processor 704 by an RF signal bearing medium 702, where the signal bearing medium 702 may be conveyed by a wireless communications medium 710 (e.g., a wireless communications medium conforming with the IEEE 802.11 standard). While the embodiments will be described in the general context of program modules that execute in conjunction with an application program that runs on an operating system on a personal computer, those skilled in the art will recognize that aspects may also be implemented in combination with other program modules.

Generally, program modules include routines, programs, components, data structures, and other types of structures that perform particular tasks or implement particular abstract data types. Moreover, those skilled in the art will appreciate that embodiments may be practiced with other computer system configurations, including hand-held devices, multiprocessor systems, microprocessor-based or programmable consumer electronics, minicomputers, mainframe computers, and comparable computing devices. Embodiments may also be practiced in distributed computing environments where tasks may be performed by remote processing devices that may be linked through a communications network. In a distributed computing environment, program modules may be located in both local and remote memory storage devices.

Embodiments may be implemented as a computer-implemented process (method), a computing system, or as an article of manufacture, such as a computer program product or computer readable media. The computer program product may be a computer storage medium readable by a computer system and encoding a computer program that includes instructions for causing a computer or computing system to perform example process(es). The computer-readable storage medium can for example be implemented via one or more of a volatile computer memory, a non-volatile memory, a hard drive, a flash drive, a floppy disk, or a compact disk, and comparable media.

Throughout this specification, the term “platform” may be a combination of software and hardware components for providing a configuration environment, which may facilitate configuration of software/hardware products and services for a variety of purposes. Examples of platforms include, but are not limited to, a hosted service executed over a plurality of servers, an application executed on a single computing device, and comparable systems. The term “server” generally refers to a computing device executing one or more software programs typically in a networked environment. However, a server may also be implemented as a virtual server (software programs) executed on one or more computing devices viewed as a server on the network. More detail on these technologies and example operations is provided below.

FIG. 8 illustrates a general purpose computing device that may be used to control the automated machine of FIG. 5 or similar manufacturing equipment in making an example capacitor device, in accordance with at least some embodiments described herein.

In a basic configuration 802, computing device 800 may include one or more processors 804 and a system memory 806. A memory bus 808 may be used for communicating between processor 804 and system memory 806.

Depending on the desired configuration, processor 804 may be of any type including but not limited to a microprocessor (μP), a microcontroller (μC), a digital signal processor (DSP), or any combination thereof. Processor 804 may include one more levels of caching, such as a level cache memory 812, a processor core 814, and registers 816. Example processor core 814 may include an arithmetic logic unit (ALU), a floating point unit (FPU), a digital signal processing core (DSP Core), or any combination thereof. An example memory controller 818 may also be used with processor 804, or in some implementations memory controller 815 may be an internal part of processor 804.

Depending on the desired configuration, system memory 806 may be of any type including but not limited to volatile memory (such as RAM), non-volatile memory (such as ROM, flash memory, etc.) or any combination thereof. System memory 806 may include an operating system 820, one or more manufacturing control applications 822, and program data 824. Manufacturing control application 822 may include a control module 826 that is arranged to control automated machine 500 of FIG. 5 and any other processes, methods and functions as discussed above. Program data 824 may include, among other data, material data 828 for controlling various aspects of the automated machine 500. This described basic configuration 802 is illustrated in FIG. 8 by those components within the inner dashed line.

Computing device 800 may have additional features or functionality, and additional interfaces to facilitate communications between basic configuration 802 and any required devices and interfaces. For example, a bus/interface controller 830 may be used to facilitate communications between basic configuration 802 and one or more data storage devices 832 via a storage interface bus 834. Data storage devices 832 may be removable storage devices 836, non-removable storage devices 838, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

System memory 806, removable storage devices 836 and non-removable storage devices 838 are examples of computer storage media. Computer storage media include, but are not limited to, RAM, ROM. EEPROM, flash memory or other memory technology. CD-ROM, digital versatile disks (DVD) or other optical storage, magnetic cassettes, magnetic tape, magnetic disk storage or other magnetic storage devices, or any other medium which may be used to store the desired information and which may be accessed by computing device 800. Any such computer storage media may be part of computing device 800.

Computing device 800 may also include an interface bus 840 for facilitating communication from various interface devices (e.g., output devices 842, peripheral interfaces 844, and communication devices 866 to basic configuration 802 via bus/interface controller 830. Example output devices 842 include a graphics processing unit 848 and an audio processing unit 850, which may be configured to communicate to various external devices such as a display or speakers via one or more A/V ports 852. Example peripheral interfaces 844 include a serial interface controller 854 or a parallel interface controller 856, which may be configured to communicate with external devices such as input devices (e.g., keyboard, mouse, pen, voice input device, touch input device, etc.) or other peripheral devices (e.g., printer, scanner, etc.) via one or more I/O ports 858. An example communication device 866 includes a network controller 860, which may be arranged to facilitate communications with one or more other computing devices 862 over a network communication link via one or more communication ports 864.

The network communication link may be one example of communication media. Communication media may be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR) and other wireless media. The term computer readable media as used herein may include both storage media and communication media.

Computing device 800 may be implemented as a portion of a physical server, virtual server, a computing cloud, or a hybrid device that include any of the above functions. Computing device 800 may also be implemented as a personal computer including both laptop computer and non-laptop computer configurations. Moreover computing device 800 may be implemented as a networked system or as part of a general purpose or specialized server.

Networks for a networked system including computing device 800 may include any topology of servers, clients, switches, routers, modems, Internet service providers, and any appropriate communication media (e.g., wired or wireless communications). A system according to embodiments may have a static or dynamic network topology. The networks may include a secure network such as an enterprise network (e.g., a LAN, WAN, or WLAN), an unsecure network such as a wireless open network (e.g., IEEE 802.11 wireless networks), or a world-wide network such (e.g., the Internet). The networks may also include a plurality of distinct networks that are adapted to operate together. Such networks are configured to provide communication between the nodes described herein. By way of example, and not limitation, these networks may include wireless media such as acoustic, RF, infrared and other wireless media. Furthermore, the networks may be portions of the same network or separate networks.

Various methods for preparing carbon nanotube-graphene composites are described herein. In some examples, methods for preparing a carbon nanotube-graphene composite may include: providing a graphite substrate that includes stacked graphene sheets, providing a carbon nanotube chemical vapor deposition catalyst, inserting the carbon nanotube chemical vapor deposition catalyst between at least a portion of the stacked graphene sheets of the graphite substrate, and/or heating the carbon nanotube chemical vapor deposition catalyst in contact with a chemical vapor deposition feedstock to a temperature suitable for growing carbon nanotubes. Various example methods may also include growing carbon nanotubes from the heated carbon nanotube chemical vapor deposition catalyst between the stacked graphene sheets of the graphite substrate for a period of time sufficient to separate at least a portion of the stacked graphene sheets of the graphite substrate using the growing carbon nanotubes. Several example methods may include cooling the carbon nanotubes and the separated graphene sheets to provide the carbon nanotube-graphene composite.

In various examples, the carbon nanotube chemical vapor deposition catalyst may be in the form of metallic nanoparticles including one or more of: Al, Mg, Sc, Ti, V, Cr, Mn, Fe, Co, Ni, Cu, Zn, Y, Zr, Nb, Mo, Tc, Ru, Rh, Pd, Ag, Cd, Lu, Hf, Ta, W, Re, Os, Ir, Pt, Au, and/or Hg. The precursor of the carbon nanotube chemical vapor deposition catalyst may be in the form of a metallic salt or an organometallic complex. The metallic salt or the organometallic complex may include one or more of: Al, Mg, Sc, Ti, V, Cr, Mn, Fe, Co, Ni, Cu, Zn, Y, Zr, Nb, Mo, Tc, Ru, Rh, Pd, Ag, Cd, Lu, Hf, Ta, W, Re, Os, Ir, Pt, Au, and/or Hg.

In some examples, providing the carbon nanotube chemical vapor deposition catalyst may include inserting a precursor of the carbon nanotube chemical vapor deposition catalyst between at least a portion of the stacked graphene sheets of the graphite substrate. In several examples, providing the carbon nanotube chemical vapor deposition catalyst may include converting the precursor into the carbon nanotube chemical vapor deposition catalyst.

In various examples of the method, the precursor of the carbon nanotube chemical vapor deposition catalyst may be FeCl₃ or ferrocene. Converting the precursor into the carbon nanotube chemical vapor deposition catalyst may include heating the precursor in the presence of a gaseous chemical reductant. The heating may be performed at a temperature in a range from about 550° C. to about 1000° C.

In several examples of the method, inserting the carbon nanotube chemical vapor deposition catalyst between at least a portion of the stacked graphene sheets may include contacting the graphite substrate with the carbon nanotube chemical vapor deposition catalyst or a precursor thereof in the form of a vapor, a liquid, or a solution.

In multiple examples of the method, the chemical vapor deposition feedstock may include one or more organic compounds having a vapor pressure of at least about 100 Torr at 550° C. The chemical vapor deposition feedstock may include one or more of carbon monoxide, methane, ethane, propane, butane, methanol, ethanol, or toluene. The chemical vapor deposition feedstock may include one or more of water vapor, H₂, N₂, NH₃, He, Ne, Ar, Kr, and/or Xe.

In various examples, the method may also include contacting the carbon nanotube-graphene composite with one or more of hydrofluoric acid, hydrochloric acid, hydrobromic acid, hydroiodic acid, nitric acid, sulfuric acid, perchloric acid, and/or a metal chelator, or an aqueous solution thereof. In some examples of the method, the carbon nanotube-graphene composite may be heated to a temperature in a range from about 550° C. to about 1000° C. in the presence of oxygen. In several examples, the method may also include contacting the carbon nanotube-graphene composite with an aqueous solution of bromine, potassium permanganate, hydrogen peroxide.

Various systems for preparing carbon nanotube-graphene composites are described herein. In some examples, systems for preparing carbon nanotube-graphene composites may include one or more of: a reaction chamber; a chemical reservoir, a pressure sensor, a heater; a temperature sensor; a gas source; and/or a controller. The reaction chamber may be configured to receive a graphite substrate that includes stacked graphene sheets. The chemical reservoir may be configured to direct a carbon nanotube chemical vapor deposition catalyst or a precursor thereof to the reaction chamber. The pressure sensor may be configured to measure a pressure in the reaction chamber. The heater may be configured to heat the reaction chamber in a range from about 550° C. to about 1000° C. The temperature sensor may be configured to measure a temperature in the reaction chamber. The gas source may be configured to direct to the reaction chamber one or more of: a reducing gas; an oxidizing gas; an inert gas; and/or a chemical vapor deposition feedstock suited for carbon nanotube deposition. The controller may be coupled to one or more of: the reaction chamber, the chemical reservoir, the gas source, the pressure sensor, the heater, and/or the temperature sensor. In several examples of the system, the controller may be programmed to: provide a graphite substrate that includes stacked graphene sheets to the reaction chamber; provide a carbon nanotube chemical vapor deposition catalyst to the reaction chamber; insert the carbon nanotube chemical vapor deposition catalyst between at least a portion of the stacked graphene sheets of the graphite substrate; and/or employ the heater and the temperature sensor to heat the carbon nanotube chemical vapor deposition catalyst in contact with the chemical vapor deposition feedstock provided by the gas source to a temperature selected to grow the carbon nanotubes. In some examples, the controller may be programmed to: grow the carbon nanotubes from the heated carbon nanotube chemical vapor deposition catalyst between the stacked graphene sheets of the graphite substrate for a period of time sufficient to separate at least a portion of the stacked graphene sheets of the graphite substrate using the carbon nanotubes; and/or employ the temperature sensor to monitor a reduction in temperature of the carbon nanotubes and the separated graphene sheets to provide the carbon nanotube-graphene composite.

In various examples, the system may include an etchant reservoir configured to deliver to the reaction chamber one or more of: hydrofluoric acid, hydrochloric acid, hydrobromic acid, hydroiodic acid, nitric acid, sulfuric acid, perchloric acid, and/or a metal chelator, or an aqueous solution thereof. The system may also include an oxidant reservoir configured to deliver to the reaction chamber one or more of: an aqueous solution of bromine, potassium permanganate, hydrogen peroxide.

Various examples of the carbon nanotube-graphene composites are described herein. In some examples, the carbon nanotube-graphene composites may include an array of stacked graphene sheets arranged in a substantially graphitic structure; and a collection of carbon nanotubes disposed between at least a portion of the stacked graphene sheets. In many examples, the carbon nanotubes may separate the portion of the stacked graphene sheets by a distance of at least about 10 nanometers.

In various examples, the carbon nanotube-graphene composite may be characterized by a graphene oxide content of less than about 0.1% by weight. The carbon nanotube-graphene composite may also be characterized by a cobalt content of less than about 0.1% by weight. The carbon nanotube-graphene composite may further be characterized by a metal content of less than about 0.1% by weight.

In various examples, the carbon nanotube-graphene composite may be characterized by a ratio of Raman D-band peak intensity divided by Raman G-band peak intensity of less than about 0.7.

In some examples, the carbon nanotubes may be characterized by an average separation of in a range from about 1 nanometer to about 50 nanometers. The carbon nanotubes may also be characterized by an average length of in a range from about 125 nanometers to about 2000 nanometers. The carbon nanotube-graphene composite may further be characterized by a maximum specific capacitance greater than about 390 Farads/gram. The carbon nanotube-graphene composite may also be characterized by a surface area greater than about 625 square meters per gram.

Various example capacitor devices are described herein. In some examples, the capacitor devices may include: a first electrode; a second electrode; a first carbon nanotube-graphene composite conductively coupled to the first electrode; and/or a second carbon nanotube-graphene composite conductively coupled to the second electrode. In various examples of the capacitor devices, the first and second carbon nanotube graphene composites may each include an array of graphene sheets arranged in a substantially graphitic structure. In some examples of the capacitor devices, a collection of carbon nanotubes may be disposed between at least a portion of the stacked graphene sheets, and the carbon nanotubes may separate the portion of the stacked graphene sheets by a distance of at least about 10 nanometers.

In various examples of the capacitor device, the carbon nanotube-graphene composite may be characterized by a graphene oxide content of less than about 0.1% by weight. The carbon nanotube-graphene composite may also be characterized by a cobalt content of less than about 0.1% by weight. The carbon nanotube-graphene composite may further be characterized by a metal content of less than about 0.1% by weight. The carbon nanotube-graphene composite may be also characterized by a ratio of Raman D-band peak intensity divided by Raman G-band peak intensity of less than about 0.7.

In various examples of the capacitor device, the carbon nanotubes may be characterized by an average separation of in a range from about 1 nanometer to about 50 nanometers. The carbon nanotubes may also be characterized by an average length of in a range from about 125 nanometers to about 2000 nanometers. The carbon nanotube-graphene composite may further be characterized by a maximum specific capacitance greater than about 390 Farads/gram. The carbon nanotube-graphene composite may also be characterized by a surface area greater than about 625 square meter per gram.

In various examples, the capacitor device may also include a material positioned in a gap between the first and second carbon nanotube-graphene composites, wherein the material may include one or more of: a dielectric, an electrolyte membrane, and/or a fluid electrolyte. The material may include an electrolyte membrane that includes: a polyoxyalkylene, a polyoxyalkylene alcohol, an alkyl ether, a cycloalkyl ether, an alkylene carbonate, a cycloalkylene carbonate, an alkanone, a cycloalkanone, a lactone, and/or a combination thereof. The material may include a fluid electrolyte that includes one or more anions of: fluoride, chloride, bromide, iodide, carboxylate, trifluoromethanesulfonate, bistrifluoromethanesulfonimidate, fluorosulfate, hexafluorophosphate, perchlorate, tetrafluoroborate, p-toluenesulfonate, and/or nitrate. The material may also include an electrolyte membrane that includes one or more of: a poly(oxy)alkylene, a polytetrafluoroethylene:perfluorosulfonic acid copolymer, a sulfonated arylene, a sulfonated polystyrene, a sulfonated poly(tetrafluoroethylene-hexafluoropropylene), a poly(vinylidene fluoride), a sulfonated poly(aryl)siloxane, a sulfonated poly(alkyl)siloxane, a sulfonated polyetheretherketone, a sulfonated polysulfone, a sulfonated polyethersulfone, a polybenzimidazole, a polyimide, a polyphenylene, a poly(4-phenoxybenzoyl-1,4-phenylene), a polybenzimidazole, a polyvinyl alcohol, a polyacrylamide, a polyethylenimine, and/or a combination thereof.

The terms “a” and “an” as used herein mean “one or more” unless the singular is expressly specified. For example, reference to “a base” may include a mixture of two or more bases, as well as a single base.

As used herein, “about” will be understood by persons of ordinary skill in the art and will vary to some extent depending upon the context in which it is used. If there are uses of the term which are not clear to persons of ordinary skill in the art, given the context in which it is used. “about” will mean up to, plus or minus 10% of the particular term.

As used herein, the terms “optional” and “optionally” mean that the subsequently described circumstance may or may not occur, so that the description includes instances where the circumstance occurs and instances where it does not.

As used herein, “substituted” refers to an organic group as defined below (e.g., an alkyl group) in which one or more bonds to a hydrogen atom contained therein may be replaced by a bond to non-hydrogen or non-carbon atoms. Substituted groups also include groups in which one or more bonds to a carbon(s) or hydrogen(s) atom may be replaced by one or more bonds, including double or triple bonds, to a heteroatom. A substituted group may be substituted with one or more substituents, unless otherwise specified. In some embodiments, a substituted group may be substituted with 1, 2, 3, 4, 5, or 6 substituents. Examples of substituent groups include: halogens (i.e., F, Cl, Br, and I); hydroxyls; alkoxy, alkenoxy, aryloxy, aralkyloxy, heterocyclyloxy, and heterocyclylalkoxy groups; carbonyls (oxo); carboxyls; esters; urethanes; oximes; hydroxylamines; alkoxyamines; aralkoxyamines; thiols; sulfides; sulfoxides; sulfones; sulfonyls; sulfonamides; amines; N-oxides; hydrazines; hydrazides; hydrazones; azides; amides; ureas; amidines; guanidines; enamines; imides; isocyanates; isothiocyanates; cyanates; thiocyanates; imines; nitro groups; nitriles (i.e., CN); and the like. A “per”-substituted compound or group is a compound or group having all or substantially all substitutable positions substituted with the indicated substituent. For example, 1,6-diiodo perfluoro hexane indicates a compound of formula C₆F₁₂I₂, where all the substitutable hydrogens have been replaced with fluorine atoms.

Substituted ring groups such as substituted cycloalkyl, aryl, heterocyclyl and heteroaryl groups also include rings and ring systems in which a bond to a hydrogen atom may be replaced with a bond to a carbon atom. Substituted cycloalkyl, aryl, heterocyclyl and heteroaryl groups may also be substituted with substituted or unsubstituted alkyl, alkenyl, and alkynyl groups as defined below.

Alkyl groups include straight chain and branched chain alkyl groups having from 1 to 12 carbon atoms, and typically from 1 to 10 carbons or, in some examples, from 1 to 8, 1 to 6, or 1 to 4 carbon atoms. Examples of straight chain alkyl groups include groups such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, tert-butyl, neopentyl, isopentyl, and 2,2-dimethylpropyl groups. Representative substituted alkyl groups may be substituted one or more times with substituents such as those listed above and include, without limitation, haloalkyl (e.g., trifluoromethyl), hydroxyalkyl, thioalkyl, aminoalkyl, alkylaminoalkyl, dialkylaminoalkyl, alkoxyalkyl, carboxyalkyl, and the like.

Cycloalkyl groups include mono-, bi- or tricyclic alkyl groups having from 3 to 12 carbon atoms in the ring(s), or, in some embodiments, 3 to 10, 3 to 8, or 3 to 4, 5, or 6 carbon atoms. Exemplary monocyclic cycloalkyl groups include, but are not limited to, cyclopropyl, cyclobutyl, cyclopentyl, cyclohexyl, cycloheptyl, and cyclooctyl groups. In some embodiments, the cycloalkyl group has 3 to 8 ring members, whereas in other embodiments, the number of ring carbon atoms ranges from 3 to 5, 3 to 6, or 3 to 7. Bi- and tricyclic ring systems include both bridged cycloalkyl groups and fused rings, such as, but not limited to, bicyclo[2.1.1]hexane, adamantyl, decalinyl, and the like. Substituted cycloalkyl groups may be substituted one or more times with non-hydrogen and non-carbon groups as defined above. However, substituted cycloalkyl groups also include rings that may be substituted with straight or branched chain alkyl groups as defined above. Representative substituted cycloalkyl groups may be mono-substituted or substituted more than once, such as, but not limited to, 2,2-, 2,3-, 2,4- 2,5- or 2,6-disubstituted cyclohexyl groups, which may be substituted with substituents such as those listed above.

Aryl groups may be cyclic aromatic hydrocarbons that do not contain heteroatoms. Aryl groups herein include monocyclic, bicyclic and tricyclic ring systems. Aryl groups include, but are not limited to, phenyl, azulenyl, heptalenyl, biphenyl, fluorenyl, phenanthrenyl, anthracenyl, indenyl, indanyl, pentalenyl, and naphthyl groups. In some embodiments, aryl groups contain 6-14 carbons, and in others from 6 to 12 or even 6-10 carbon atoms in the ring portions of the groups. In some embodiments, the aryl groups may be phenyl or naphthyl. Although the phrase “aryl groups” may include groups containing fused rings, such as fused aromatic-aliphatic ring systems (e.g., indanyl, tetrahydronaphthyl, and the like), “aryl groups” does not include aryl groups that have other groups, such as alkyl or halo groups, bonded to one of the ring members. Rather, groups such as tolyl may be referred to as substituted aryl groups. Representative substituted aryl groups may be mono-substituted or substituted more than once. For example, monosubstituted aryl groups include, but are not limited to, 2-, 3-, 4-, 5-, or 6-substituted phenyl or naphthyl groups, which may be substituted with substituents such as those listed above.

Aralkyl groups may be alkyl groups as defined above in which a hydrogen or carbon bond of an alkyl group may be replaced with a bond to an aryl group as defined above. In some embodiments, aralkyl groups contain 7 to 16 carbon atoms, 7 to 14 carbon atoms, or 7 to 10 carbon atoms. Substituted aralkyl groups may be substituted at the alkyl, the aryl or both the alkyl and aryl portions of the group. Representative aralkyl groups include but are not limited to benzyl and phenethyl groups and fused (cycloalkylaryl)alkyl groups such as 4-indanylethyl. Representative substituted aralkyl groups may be substituted one or more times with substituents such as those listed above.

Heterocyclyl groups include aromatic (also referred to as heteroaryl) and non-aromatic ring compounds containing 3 or more ring members of which one or more may be a heteroatom such as, but not limited to, N, O, and S. In some embodiments, the heterocyclyl group contains 1, 2, 3 or 4 heteroatoms. In some embodiments, heterocyclyl groups include mono-, bi- and tricyclic rings having 3 to 16 ring members, whereas other such groups have 3 to 6, 3 to 10, 3 to 12, or 3 to 14 ring members. Heterocyclyl groups encompass aromatic, partially unsaturated and saturated ring systems, such as, for example, imidazolyl, imidazolinyl and imidazolidinyl groups. The phrase “heterocyclyl group” includes fused ring species including those with fused aromatic and non-aromatic groups, such as, for example, benzotriazolyl, 2,3-dihydrobenzo[1,4]dioxinyl, and benzo[1,3]dioxolyl. The phrase also includes bridged polycyclic ring systems containing a heteroatom such as, but not limited to, quinuclidyl. However, the phrase does not include heterocyclyl groups that have other groups, such as alkyl, oxo or halo groups, bonded to one of the ring members. Rather, these may be referred to as “substituted heterocyclyl groups.” Heterocyclyl groups include, but are not limited to, aziridinyl, azetidinyl, pyrrolidinyl, imidazolidinyl, pyrazolidinyl, thiazolidinyl, tetrahydrothiophenyl, tetrahydrofuranyl, dioxolyl, furanyl, thiophenyl, pyrrolyl, pyrrolinyl, imidazolyl, imidazolinyl, pyrazolyl, pyrazolinyl, triazolyl, tetrazolyl, oxazolyl, isoxazolyl, thiazolyl, thiazolinyl, isothiazolyl, thiadiazolyl, oxadiazolyl, piperidyl, piperazinyl, morpholinyl, thiomorpholinyl, tetrahydropyranyl, tetrahydrothiopyranyl, oxathiane, dioxyl, dithianyl, pyranyl, pyridyl, pyrimidinyl, pyridazinyl, pyrazinyl, triazinyl, dihydropyridyl, dihydrodithiinyl, dihydrodithionyl, homopiperazinyl, quinuclidyl, indolyl, indolinyl, isoindolyl, azaindolyl (pyrrolopyridyl), indazolyl, indolizinyl, benzotriazolyl, benzimidazolyl, benzofuranyl, benzothiophenyl, benzthiazolyl, benzoxadiazolyl, benzoxazinyl, benzodithiinyl, benzoxathiinyl, benzothiazinyl, benzoxazolyl, benzothiazolyl, benzothiadiazolyl, benzo[1,3]dioxolyl, pyrazolopyridyl, imidazopyridyl (azabenzimidazolyl), triazolopyridyl, isoxazolopyridyl, purinyl, xanthinyl, adeninyl, guaninyl, quinolinyl, isoquinolinyl, quinolizinyl, quinoxalinyl, quinazolinyl, cinnolinyl, phthalazinyl, naphthyridinyl, pteridinyl, thianaphthyl, dihydrobenzothiazinyl, dihydrobenzofuranyl, dihydroindolyl, dihydrobenzodioxinyl, tetrahydroindolyl, tetrahydroindazolyl, tetrahydrobenzimidazolyl, tetrahydrobenzotriazolyl, tetrahydropyrrolopyridyl, tetrahydropyrazolopyridyl, tetrahydroimidazopyridyl, tetrahydrotriazolopyridyl, and tetrahydroquinolinyl groups. Representative substituted heterocyclyl groups may be mono-substituted or substituted more than once, such as, but not limited to, pyridyl or morpholinyl groups, which may be 2, 3-, 4-, 5-, or 6-substituted, or disubstituted with various substituents such as those listed above.

Heteroaryl groups may be aromatic ring compounds containing 5 or more ring members, of which one or more may be a heteroatom such as, but not limited to, N, O, and S. Heteroaryl groups include, but are not limited to, groups such as pyrrolyl, pyrazolyl, triazolyl, tetrazolyl, oxazolyl, isoxazolyl, thiazolyl, pyridinyl, pyridazinyl, pyrimidinyl, pyrazinyl, thiophenyl, benzothiophenyl, furanyl, benzofuranyl, indolyl, azaindolyl (pyrrolopyridinyl), indazolyl, benzimidazolyl, imidazopyridinyl (azabenzimidazolyl), pyrazolopyridinyl, triazolopyridinyl, benzotriazolyl, benzoxazolyl, benzothiazolyl, benzothiadiazolyl, imidazopyridinyl, isoxazolopyridinyl, thianaphthyl, purinyl, xanthinyl, adeninyl, guaninyl, quinolinyl, isoquinolinyl, tetrahydroquinolinyl, quinoxalinyl, and quinazolinyl groups. Heteroaryl groups include fused ring compounds in which all rings may be aromatic such as indolyl groups and include fused ring compounds in which only one of the rings may be aromatic, such as 2,3-dihydro indolyl groups. Although the phrase “heteroaryl groups” includes fused ring compounds, the phrase does not include heteroaryl groups that have other groups bonded to one of the ring members, such as alkyl groups. Rather, heteroaryl groups with such substitution may be referred to as “substituted heteroaryl groups.” Representative substituted heteroaryl groups may be substituted one or more times with various substituents such as those listed above.

Heteroaralkyl groups may be alkyl groups as defined above in which a hydrogen or carbon bond of an alkyl group may be replaced with a bond to a heteroaryl group as defined above. Substituted heteroaralkyl groups may be substituted at the alkyl, the heteroaryl or both the alkyl and heteroaryl portions of the group. Representative substituted heteroaralkyl groups may be substituted one or more times with substituents such as those listed above.

Groups described herein having two or more points of attachment (i.e., divalent, trivalent, or polyvalent) within the compound of the technology may be designated by use of the suffix, “ene.” For example, divalent alkyl groups may be alkylene groups, divalent aryl groups may be arylene groups, divalent heteroaryl groups may be heteroarylene groups, and so forth. In particular, certain polymers may be described by use of the suffix “ene” in conjunction with a term describing the polymer repeat unit. For example, the compound “poly-para-phenylene” includes a repeat unit phenyl linked at two points of attachment, located para with respect to each other on the ring. In another example, polymers generally may be referred to in the same manner, for example, a polyarylene is a polymer linked at two points of attachment through an aryl group (e.g., poly-para-phenylene). Other examples include polyheteroarylenes (e.g., polythiophene), polyarylene vinylenes (e.g., poly-para-phenylene vinylene), polyheteroarylene vinylenes (e.g., polythiophene vinylene), and so on. Note that some common names in the art may not follow the above-described pattern. For example, the polymer commonly known as “polypyrrole” is a polyheteroarylene, named without the “ene” suffix.

Alkoxy groups may be hydroxyl groups (—OH) in which the bond to the hydrogen atom may be replaced by a bond to a carbon atom of a substituted or unsubstituted alkyl group as defined above. Examples of linear alkoxy groups include, but are not limited to, methoxy, ethoxy, propoxy, butoxy, pentoxy, hexoxy, and the like. Examples of branched alkoxy groups include, but are not limited to, isopropoxy, sec-butoxy, tert-butoxy, isopentoxy, isohexoxy, and the like. Examples of cycloalkoxy groups include, but are not limited to, cyclopropyloxy, cyclobutyloxy, cyclopentyloxy, cyclohexyloxy, and the like. Representative substituted alkoxy groups may be substituted one or more times with substituents such as those listed above.

The term “amine” (or “amino”), as used herein, refers to NR₅R₆ groups, wherein R₅ and R₆ may be independently hydrogen, or a substituted or unsubstituted alkyl, alkenyl, alkynyl, cycloalkyl, aryl, aralkyl, heterocyclylalkyl or heterocyclyl group as defined herein. In some embodiments, the amine may be alkylamino, dialkylamino, arylamino, or alkylarylamino. In other embodiments, the amine may be NH₂, methylamino, dimethylamino, ethylamino, diethylamino, propylamino, isopropylamino, phenylamino, or benzylamino. The term “alkylamino” may be defined as NR₇R₈, wherein at least one of R₇ and R₈ may be alkyl and the other may be alkyl or hydrogen. The term “arylamino” may be defined as NR₉R₁₀, wherein at least one of R₉ and R₁₀ may be aryl and the other may be aryl or hydrogen.

The term “halogen” or “halo.” as used herein, refers to bromine, chlorine, fluorine, or iodine. In some embodiments, the halogen may be fluorine. In other embodiments, the halogen may be chlorine or bromine.

There is little distinction left between hardware and software implementations of aspects of systems; the use of hardware or software is generally (but not always, in that in certain contexts the choice between hardware and software may become significant) a design choice representing cost vs. efficiency tradeoffs. There are various vehicles by which processes and/or systems and/or other technologies described herein may be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples may be implemented, individually and/or collectively, by a wide range of hardware, software, firmware, or virtually any combination thereof. In one embodiment, several portions of the subject matter described herein may be implemented via Application Specific Integrated Circuits (ASICs). Field Programmable Gate Arrays (FPGAs), digital signal processors (DSPs), or other integrated formats. However, those skilled in the art will recognize that some aspects of the embodiments disclosed herein, in whole or in part, may be equivalently implemented in integrated circuits, as one or more computer programs running on one or more computers (e.g., as one or more programs running on one or more computer systems), as one or more programs running on one or more processors (e.g. as one or more programs running on one or more microprocessors), as firmware, or as virtually any combination thereof, and that designing the circuitry and/or writing the code for the software and or firmware would be well within the skill of one of skill in the art in light of this disclosure.

The present disclosure is not to be limited in terms of the particular embodiments described in this application, which are intended as illustrations of various aspects. Many modifications and variations may be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, systems, or components, which can, of course, vary. It is also to be understood that the terminology used herein is for the purpose of describing particular embodiments only, and is not intended to be limiting.

In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Versatile Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein may be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops.

A typical manufacturing system may be implemented utilizing any suitable commercially available components, such as those typically found in data computing/communication and/or network computing/communication systems. The herein described subject matter sometimes illustrates different components contained within, or coupled together with, different other components. It is to be understood that such depicted architectures are merely exemplary, and that in fact many other architectures may be implemented which achieve the same functionality. In a conceptual sense, any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermediate components. Likewise, any two components so associated may also be viewed as being “operably connected”, or “operably coupled”, to each other to achieve the desired functionality, and any two components capable of being so associated may also be viewed as being “operably couplable”, to each other to achieve the desired functionality. Specific examples of operably couplable include but are not limited to physically connectable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group. As will be understood by one skilled in the art, for any and all purposes, such as in terms of providing a written description, all ranges disclosed herein also encompass any and all possible sub-ranges and combinations of sub-ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into sub-ranges as discussed above. Finally, as will be understood by one skilled in the art, a range includes each individual member. For example, a group having 1-3 cells refers to groups having 1, 2, or 3 cells. Similarly, a group having 1-5 cells refers to groups having 1, 2, 3, 4, or 5 cells, and so forth. While various aspects and embodiments have been disclosed herein, other aspects and embodiments will be apparent to those skilled in the art.

The various aspects and embodiments disclosed herein are for purposes of illustration and are not intended to be limiting, with the true scope and spirit being indicated by the following claims.

What is claimed is:

1. A method of preparing a carbon nanotube-graphene composite, comprising:
providing a graphite substrate that includes stacked graphene sheets;
providing a carbon nanotube chemical vapor deposition catalyst;
inserting the carbon nanotube chemical vapor deposition catalyst between at least a portion of the stacked graphene sheets of the graphite substrate;
heating the carbon nanotube chemical vapor deposition catalyst in contact with a chemical vapor deposition feedstock to a temperature suitable for growing carbon nanotubes;
growing carbon nanotubes from the heated carbon nanotube chemical vapor deposition catalyst between the stacked graphene sheets of the graphite substrate for a period of time sufficient to separate at least a portion of the stacked graphene sheets of the graphite substrate using the growing carbon nanotubes; and
cooling the carbon nanotubes and the separated graphene sheets to provide the carbon nanotube-graphene composite.

2. The method of claim 1, wherein the carbon nanotube chemical vapor deposition catalyst is in the form of metallic nanoparticles comprising one or more of: Al, Mg, Sc, Ti, V, Cr, Mn, Fe, Co, Ni, Cu, Zn, Y, Zr, Nb, Mo, Tc, Ru, Rh, Pd, Ag, Cd, Lu, Hf, Ta, W, Re, Os, Ir, Pt, Au, or Hg.

3. The method of claim 1, wherein providing the carbon nanotube chemical vapor deposition catalyst includes:
inserting a precursor of the carbon nanotube chemical vapor deposition catalyst between at least a portion of the stacked graphene sheets of the graphite substrate; and
converting the precursor into the carbon nanotube chemical vapor deposition catalyst.

4. The method of claim 3, wherein:
the precursor of the carbon nanotube chemical vapor deposition catalyst is in the form of a metallic salt or an organometallic complex; and
the metallic salt or the organometallic complex comprises one or more of: Al, Mg, Sc, Ti, V, Cr, Mn, Fe, Co, Ni, Cu, Zn, Y, Zr, Nb, Mo, Tc, Ru, Rh, Pd, Ag, Cd, Lu, Hf, Ta, W, Re, Os, Ir, Pt, Au, or Hg.

5. The method of claim 3, wherein the precursor of the carbon nanotube chemical vapor deposition catalyst is one or more of FeCl₃, ferrocene, CoCl₂, FeSO₄, CoSO₄.

6. The method of claim 3, wherein converting the precursor into the carbon nanotube chemical vapor deposition catalyst includes heating the precursor in the presence of a gaseous chemical reductant.

7. The method of claim 1, wherein inserting the carbon nanotube chemical vapor deposition catalyst between at least a portion of the stacked graphene sheets includes contacting the graphite substrate with the carbon nanotube chemical vapor deposition catalyst or a precursor thereof in the form of a vapor, a liquid, or a solution.

8. The method of claim 1, wherein heating is performed at a temperature in a range from about 550° C. to about 1000° C.

9. The method of claim 8, wherein the chemical vapor deposition feedstock includes one or more organic compounds having a vapor pressure of at least about 100 Torr at 550° C.

10. The method of claim 9, wherein the chemical vapor deposition feedstock includes one or more of carbon monoxide, methane, ethane, propane, butane, methanol, ethanol, toluene, and an acetylen/H₂ forming gas.

11. The method of claim 9, wherein the chemical vapor deposition feedstock includes one or more of water vapor, H₂, N₂, NH₃, He, Ne, Ar, Kr, and/or Xe.

12. The method of claim 1, further comprising contacting the carbon nanotube-graphene composite with one or more of hydrofluoric acid, hydrochloric acid, hydrobromic acid, hydroiodic acid, nitric acid, sulfuric acid, perchloric acid, and/or a metal chelator, or an aqueous solution thereof.

13. The method of claim 1, wherein the carbon nanotube-graphene composite is heated to a temperature in a range from about 550° C. to about 1000° C. in the presence of oxygen and H₂/Ar protection gas.

14. The method of claim 1, further comprising contacting the carbon nanotube-graphene composite with an aqueous solution of bromine, potassium permanganate, hydrogen peroxide.

15. A system for preparing a carbon nanotube-graphene composite, the system comprising:
a reaction chamber configured to receive a graphite substrate that includes stacked graphene sheets;
a chemical reservoir configured to direct a carbon nanotube chemical vapor deposition catalyst or a precursor thereof to the reaction chamber;
a gas source configured to direct to the reaction chamber: a reductant gas; an oxidant gas; an inert gas; and a chemical vapor deposition feedstock suited for carbon nanotube deposition;
a pressure sensor configured to measure a pressure in the reaction chamber;
a heater configured to heat the reaction chamber to in a range from about 550° C. to about 1000° C.;
a temperature sensor configured to measure a temperature in the reaction chamber; and
a controller coupled to the reaction chamber, the chemical reservoir, the gas source, the pressure sensor, the heater, and the temperature sensor, where the controller is programmable to:
provide a graphite substrate that includes stacked graphene sheets to the reaction chamber;
provide a carbon nanotube chemical vapor deposition catalyst to the reaction chamber,
insert the carbon nanotube chemical vapor deposition catalyst between at least a portion of the stacked graphene sheets of the graphite substrate;
employ the heater and the temperature sensor to heat the carbon nanotube chemical vapor deposition catalyst in contact with a chemical vapor deposition feedstock provided by the gas source to a temperature selected to grow the carbon nanotubes;
grow the carbon nanotubes from the heated carbon nanotube chemical vapor deposition catalyst between the stacked graphene sheets of the graphite substrate for a period of time sufficient to separate at least a portion of the stacked graphene sheets of the graphite substrate with the carbon nanotubes; and
employ the temperature sensor to monitor a reduction in temperature of the carbon nanotubes and the separated graphene sheets to provide the carbon nanotube-graphene composite.

16. The system of claim 15, further comprising an etchant reservoir configured to deliver to the reaction chamber one or more of: hydrofluoric acid, hydrochloric acid, hydrobromic acid, hydroiodic acid, nitric acid, sulfuric acid, perchloric acid, and/or a metal chelator, or an aqueous solution thereof.

17. The system of claim 15, further comprising an oxidant reservoir configured to deliver to the reaction chamber one or more of: an aqueous solution of bromine, potassium permanganate, hydrogen peroxide.

18. A carbon nanotube-graphene composite, comprising:
an array of stacked graphene sheets arranged in a substantially graphitic structure; and
a collection of carbon nanotubes disposed between at least a portion of the stacked graphene sheets, wherein the carbon nanotubes separate the portion of the stacked graphene sheets by a distance of at least about 10 nanometers.

19. The carbon nanotube-graphene composite of claim 18, characterized by a graphene oxide content of less than about 0.1% by weight.

20. The carbon nanotube-graphene composite of claim 18, characterized by a cobalt content of less than about 0.1% by weight.

21. The carbon nanotube-graphene composite of claim 20, characterized by a metal content of less than about 0.1% by weight.

22. The carbon nanotube-graphene composite of claim 18, characterized by a ratio of Raman D-band peak intensity divided by Raman G-band peak intensity of less than about 0.7.

23. The carbon nanotube-graphene composite of claim 18, wherein the carbon nanotubes are characterized by an average separation of in a range from about 1 nanometer to about 50 nanometers.

24. The carbon nanotube-graphene composite of claim 18, wherein the carbon nanotubes are characterized by an average length of in a range from about 125 nanometers to about 2000 nanometers.

25. The carbon nanotube-graphene composite of claim 18, characterized by a maximum specific capacitance greater than about 390 Farads/gram.

26. The carbon nanotube-graphene composite of claim 18, characterized by a surface area greater than about 625 square meters per gram.

27. A capacitor device, comprising:
a first electrode;
a second electrode;
a first carbon nanotube-graphene composite conductively coupled to the first electrode;
a second carbon nanotube-graphene composite conductively coupled to the second electrode,
wherein the first and second carbon nanotube graphene composites each include:
an array of graphene sheets arranged in a substantially graphitic structure; and
a collection of carbon nanotubes disposed between at least a portion of the stacked graphene sheets, wherein the carbon nanotubes separate the portion of the stacked graphene sheets by a distance of at least about 10 nanometers.

28. The capacitor device of claim 27, wherein the carbon nanotube-graphene composite is characterized by a graphene oxide content of less than about 0.1% by weight.

29. The capacitor device of claim 27, wherein the carbon nanotube-graphene composite is characterized by a cobalt content of less than about 0.1% by weight.

30. The capacitor device of claim 27, wherein the carbon nanotube-graphene composite is characterized by a metal content of less than about 0.1% by weight.

31. The capacitor device of claim 27, wherein the carbon nanotube-graphene composite is characterized by a ratio of Raman D-band peak intensity divided by Raman G-band peak intensity of less than about 0.7.

32. The capacitor device of claim 27, wherein the carbon nanotubes are characterized by an average separation of in a range from about 1 nanometer to about 50 nanometers.

33. The capacitor device of claim 27, wherein the carbon nanotubes are characterized by an average length of in a range from about 125 nanometers to about 2000 nanometers.

34. The capacitor device of claim 27, wherein the carbon nanotube-graphene composite is characterized by a maximum specific capacitance greater than about 390 Farads/gram.

35. The capacitor device of claim 27, wherein the carbon nanotube-graphene composite is characterized by a surface area greater than about 625 square meter per gram.

36. The capacitor device of claim 27, further comprising a material positioned in a gap between the first and second carbon nanotube-graphene composites, wherein the material includes one or more of a dielectric, an electrolyte membrane, and/or a fluid electrolyte.

37. The capacitor device of claim 36, wherein the material includes an electrolyte membrane that comprises a polyoxyalkylene, a polyoxyalkylene alcohol, an alkyl ether, a cycloalkyl ether, an alkylene carbonate, a cycloalkylene carbonate, an alkanone, a cycloalkanone, a lactone, or a combination thereof.

38. The capacitor device of claim 36, wherein the material includes a fluid electrolyte that comprises one or more anions selected from the group consisting of: fluoride, chloride, bromide, iodide, carboxylate, trifluoromethanesulfonate, bistrifluoromethanesulfonimidate, fluorosulfate, hexafluorophosphate, perchlorate, tetrafluoroborate, p-toluenesulfonate, and nitrate.

39. The capacitor device of claim 36, wherein the material includes an electrolyte membrane that comprises one of: a poly(oxy)alkylene, a polytetrafluoroethylene:perfluorosulfonic acid copolymer, a sulfonated arylene, a sulfonated polystyrene, a sulfonated poly(tetrafluoroethylene-hexafluoropropylene), a poly(vinylidene fluoride), a sulfonated poly(aryl)siloxane, a sulfonated poly(alkyl)siloxane, a sulfonated polyetheretherketone, a sulfonated polysulfone, a sulfonated polyethersulfone, a polybenzimidazole, a polyimide, a polyphenylene, a poly(4-phenoxybenzoyl-1,4-phenylene), a polybenzimidazole, a polyvinyl alcohol, a polyacrylamide, a polyethylenimine, or a combination thereof.
